(19) United States
(12) Patent Application Publication
(10) Pub. No.: US 2026/0293479 A1
(43) Pub. Date: Sep. 24, 2026

(54) ELECTRO-OPTICAL DEVICE AND ELECTRONIC APPARATUS

(71) Applicant: SEIKO EPSON CORPORATION, Tokyo (JP)

(72) Inventor: Takumi KODAMA, CHINO-SHI (JP)

(73) Assignee: SEIKO EPSON CORPORATION, Tokyo (JP)

(21) Appl. No.: 19/568,861

(22) Filed: Mar. 17, 2026

(30) Foreign Application Priority Data
Mar. 18, 2025 (JP) 2025-043293

(51) Int. Cl. H10K 59/131; G09G 3/3233

(52) U.S. Cl. CPC H10K 59/1315; G09G 3/3233; G09G 2300/0426; G09G 2300/0452; G09G 2300/0842; G09G 2310/08

(57) ABSTRACT

An interconnection, a data line, and another interconnection extend in a Y direction and are disposed along an X direction in this order by patterning a third interconnection layer. An interconnection formed of a second interconnection layer is coupled to the interconnection formed of the third interconnection layer via a contact hole and is coupled to the another interconnection formed of the third interconnection layer via a contact hole, and an interconnection formed of a fourth interconnection layer is coupled to the interconnection via a contact hole and is coupled to the another interconnection formed of the third interconnection layer via a contact hole. The contact holes are each arranged along the Y direction, and a coupling length per unit length thereof is longer than a non-coupling length.

The present application is based on, and claims priority from JP Application Serial Number 2025-043293, filed Mar. 18, 2025, the disclosure of which is hereby incorporated by reference herein in its entirety.

### BACKGROUND

### 1. Technical Field

The present disclosure relates to an electro-optical device and an electronic apparatus.

### 2. Related Art

There has been known an electro-optical device using, for example, an organic light emitting diode (OLED) as a display element. In the electro-optical device, a pixel circuit including a transistor for causing a current to flow through the display element, or the like is provided corresponding to each pixel of an image to be displayed.

As the resolution and definition increase, an interval between adjacent pixel circuits and various interconnections is narrowed. When an interval between two interconnections is narrowed, a voltage variation due to one interconnection is likely to affect the other interconnection, that is, interference is likely to occur.

Therefore, a technique has been proposed in which data lines, electrodes which couple transistors to pixel electrodes of a display element, and so on are surrounded by a power supply interconnection in plan view to thereby suppress the influence due to a voltage variation (see, e.g., JP-A-2023-146728). In the above technique, since the interconnection formed in the same interconnection layer as the data lines is adjacent to the data lines on the left and right, the influence due to the voltage variation of the data lines is reduced.

JP-A-2023-146728 is an example of the related art.

In recent years, an electro-optical device is strongly required to have high resolution and high definition. In order to satisfy the demand for high resolution and high definition, it is necessary to narrow the pitch of each portion, but when the pitch between the interconnections is narrowed, the connection via parasitic capacitances becomes strong. Therefore, there is a circumstance that it is difficult to satisfy the high resolution and the high definition while suppressing the interference only by the above technique.

### SUMMARY

An electro-optical device according to an aspect of the present disclosure includes: a first interconnection, a first data line, and a second interconnection which are formed of a first interconnection layer; a first pixel circuit configured to take an optical state according to a data signal supplied to the first data line; a lower layer interconnection formed of an interconnection layer as a lower layer of the first interconnection layer; and an upper layer interconnection formed of an interconnection layer as an upper layer of the first interconnection layer, wherein the first interconnection, the first data line, and the second interconnection extend along a first direction and are arranged in order in a second direction, the lower layer interconnection overlaps the first interconnection and the second interconnection in plan view, the upper layer interconnection overlaps the first interconnection and the second interconnection in plan view, the first interconnection and the lower layer interconnection are coupled via a first contact hole configured to penetrate a first insulating layer, a coupling length by the first contact hole is longer than a non-coupling length per first unit length along the first direction, the second interconnection and the lower layer interconnection are coupled via a second contact hole configured to penetrate the first insulating layer, a coupling length by the second contact hole per second unit length along the first direction is longer than a non-coupling length per second unit length along the first direction, the first interconnection and the upper layer interconnection are coupled via a third contact hole configured to penetrate a second insulating layer, a coupling length by the third contact hole is longer than a non-coupling length per the first unit length, the second interconnection and the upper layer interconnection are coupled via a fourth contact hole configured to penetrate the second insulating layer, and a coupling length by the fourth contact hole is longer than a non-coupling length per the first unit length.

### BRIEF DESCRIPTION OF THE DRAWINGS

FIG. 1 is a perspective view showing an electro-optical device according to an embodiment.

FIG. 2 is a block diagram illustrating a configuration of a main part of the electro-optical device.

FIG. 3 is a circuit diagram illustrating a configuration of a main part of the electro-optical device.

FIG. 4 is a plan view illustrating an arrangement of display elements and the like in the electro-optical device.

FIG. 5 is a diagram illustrating a configuration of a pixel circuit in a display region.

FIG. 6 is a timing chart illustrating an operation of the electro-optical device.

FIG. 7 is a timing chart illustrating an operation of the electro-optical device.

FIG. 8 is a diagram illustrating an operation of the electro-optical device.

FIG. 9 is a diagram illustrating an operation of the electro-optical device.

FIG. 10 is a diagram illustrating an operation of the electro-optical device.

FIG. 11 is a diagram illustrating an operation of the electro-optical device.

FIG. 12 is a diagram illustrating an operation of the electro-optical device.

FIG. 13 is a diagram illustrating an operation of the electro-optical device.

FIG. 14 is a cross-sectional view of the main part of the electro-optical device.

FIG. 15 is a plan view illustrating a semiconductor region and the like of the electro-optical device.

FIG. 16 is a plan view illustrating interconnections and the like in a first interconnection layer of the electro-optical device.

FIG. 17 is a plan view illustrating capacitance electrodes of the electro-optical device.

FIG. 18 is a plan view illustrating interconnections and the like in a second interconnection layer of the electro-optical device.

FIG. 19 is a plan view illustrating interconnections and the like in a third interconnection layer of the electro-optical device.

FIG. 20 is a plan view illustrating interconnections and the like in a fourth interconnection layer of the electro-optical device.

FIG. 21 is a plan view illustrating pixel electrodes of the electro-optical device.

FIG. 22 is a plan view showing contact holes in the second and third interconnection layers.

FIG. 23 is a plan view showing contact holes in the third and fourth interconnection layers.

FIG. 24 is a plan view showing interconnections and the like formed of a third interconnection layer in an electro-optical device according to a modified example.

FIG. 25 is a plan view illustrating interconnections and the like in a fourth interconnection layer of the electro-optical device.

FIG. 26 is a perspective view illustrating a head-mounted display using the electro-optical device.

FIG. 27 is a diagram illustrating an optical configuration of the head-mounted display.

### DESCRIPTION OF EMBODIMENTS

Hereinafter, an electro-optical device according to an embodiment of the present disclosure will be described with reference to the drawings. Note that, in the drawings, dimensions and scales of the respective parts are appropriately made different from real ones. The embodiment explained below is a preferred specific example. Therefore various technically preferable limitations are added to the embodiment. However, the scope of the present disclosure is not limited to the embodiment unless there is particularly a description to the effect that the present disclosure is limited thereto in the following explanation.

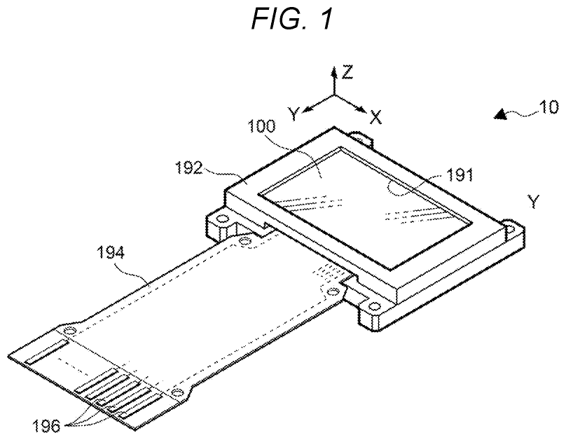

FIG. 1 is a perspective view illustrating an electro-optical device 10. The electro-optical device 10 is, for example, a micro display panel that displays an image in a head-mounted display or the like. The electro-optical device 10 includes a plurality of pixel circuits, drive circuits that drive the pixel circuits, and the like. The pixel circuits and the drive circuits are integrated on a semiconductor substrate. The semiconductor substrate is typically a silicon substrate, but may be a semiconductor substrate other than silicon.

As illustrated in the drawing, the electro-optical device 10 is accommodated in a frame-shaped case 192 having an opening 191. The display region 100 of the electro-optical device 10 is exposed in the opening 191. One end of a flexible printed circuit (FPC) board 194 is coupled to the electro-optical device 10. A plurality of terminals 196 are provided at the other end of the FPC board 194. The plurality of terminals 196 are coupled to a host device (not illustrated). The host device supplies video data to the electro-optical device 10. The video data is data representing video images displayed by the electro-optical device 10 in time series.

In the drawings, an X direction indicates a horizontal direction of a video image displayed by the electro-optical device 10, and a Y direction indicates a vertical direction of the video image. A two-dimensional plane defined by the X direction and the Y direction is a substrate surface of the semiconductor substrate. A Z direction is a normal direction of the substrate surface of the semiconductor substrate, is perpendicular to the X direction and the Y direction, and indicates an exit direction of light emitted from an OLED which is a display element described later.

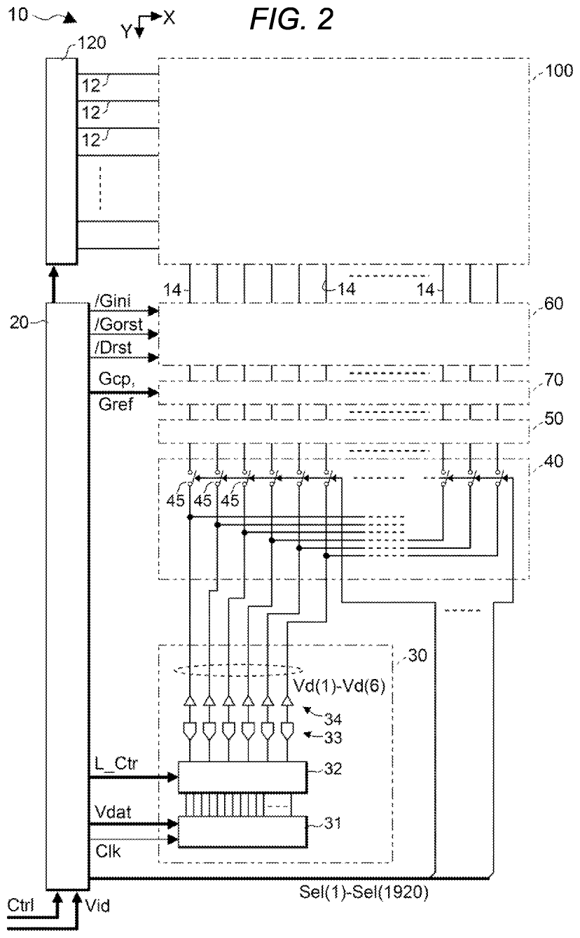

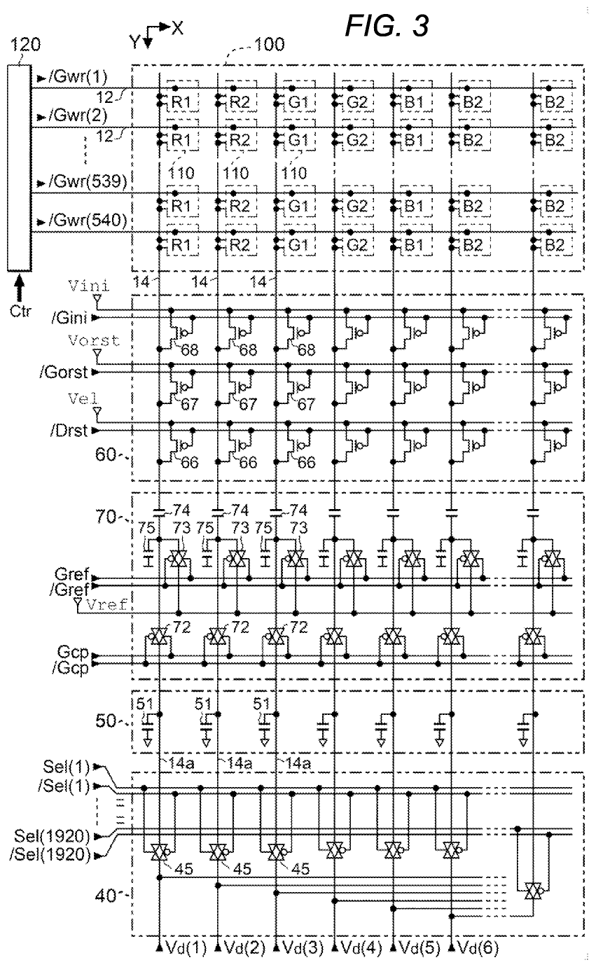

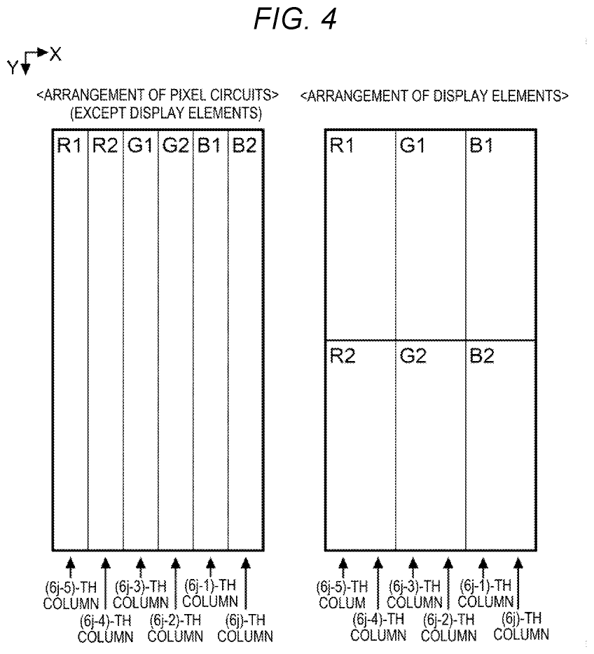

FIG. 2 is a block diagram illustrating an electric configuration of the electro-optical device 10, and FIG. 3 is a diagram illustrating a configuration of a main part of the electro-optical device 10. FIG. 4 is a plan view illustrating an array of pixel circuits excluding display elements and an array of display elements in the pixel circuits in the electro-optical device 10.

As illustrated in FIG. 2, the electro-optical device 10 includes a control circuit 20, a data signal output circuit 30, a switch group 40, a capacitive element group 50, an initialization circuit 60, an auxiliary circuit 70, a display region 100, and a scanning line drive circuit 120.

In the electro-optical device 10, for example, 540 rows of scanning lines 12 are provided to extend in the X direction in the drawing, and 11,520 (=1920×3×2) columns of data lines 14 are provided to extend in the Y direction and are provided to be electrically insulated from the scanning lines 12.

In order to distinguish rows in the scanning line 12, the rows are called rows 1, 2, 3, . . . , 539, and 540 in order from the top in the drawing. In order to generally describe the scanning line 12 without specifying a row, a notation “i-th row” is used, where i is an integer of 1 or more and 540 or less.

In order to distinguish columns in the data line 14, the columns are called columns 1, 2, 3, . . . , 11,520 in order from the left in the drawing. The data lines 14 are grouped every six columns. When an integer j of 1 or more and 960 or less is used in order to generalize and describe the groups, a j-th group from the left contains a total of six columns of the data lines 14, that is, the data lines 14 in a (6j-5)-th column, a (6j-4)-th column, a (6j-3)-th column, a (6j-2)-th column, a (6j-1)-th column, and a (6j)-th column.

The pixel circuit 110R1 or 110R2 includes a display element that emits light containing a red component, the pixel circuit 110G1 or 110R2 includes a display element that emits light containing a green component, and the pixel circuit 110B1 or 110B2 includes a display element that emits light containing a blue component.

When the pixel circuits 110R1, 110R2, 110G1, 110G2, 110B1, and 110B2 are generally described without specifying colors, the reference numeral of the pixel circuit is simply described as 110.

The pixel circuits 110 excluding the display elements are provided corresponding to the scanning lines 12 arranged in 540 rows and the data lines 14 arranged in 11,520 columns. In terms of the intersection between the scanning line 12 in the i-th row and the data lines 14 in the (6j-5)-th to (6j)-th columns, as shown in the left column of FIG. 4, six pixel circuits 110R1, 110R2, 110G1, 110G2, 110B1, and 110B2 are provided in a 1×6 matrix in order along the X direction.

While the pixel circuits 110 excluding the display elements are arranged in the 1×6 matrix, the display elements are arranged in a 2×3 matrix as shown in the right column of FIG. 4. Therefore, the size of the pixel circuits 110 excluding the display elements in the X direction is ½ times the size of the display elements in the X direction, and the size of the pixel circuits 110 excluding the display element in the Y direction is twice the size of the display elements in the Y direction.

In FIG. 4, the pixel circuits 110R1, 110R2, 110G1, 110G2, 110B1, and 110B2 excluding the display elements and the display elements corresponding to these pixel circuits are denoted by R1, R2, G1, G2, B1, and B2 in order for simplification and distinction.

In addition, in FIG. 4, the pixel circuits which exclude the display elements and are shown in the left column and the display elements which correspond to the pixel circuits and are shown in the right column are aligned in the Y direction for the sake of description, but in reality, as described later, the display elements are shifted in the Y direction with respect to the pixel circuits excluding the display elements.

A region where the display elements are arranged is the display region 100.

The pixel circuits 110 excluding the display elements are arranged in a matrix of 590 rows×11,520 columns, and the display elements are arranged in a matrix of vertical 1,080 rows×horizontal 5,760 columns. Three display elements adjacent to each other in the X direction in plan view correspond to the red pixel circuit 110R, the green pixel circuit 110G, and the blue pixel circuit 110 G in order and a color of one dot is expressed by additive color mixing of these three colors.

Therefore, in the embodiment, an image in which color dots are arranged in a matrix of vertical 1,080 rows×horizontal 1,920 columns is displayed.

Note that the pixel circuits 110R, 110G, and 110B represent a red component, a green component, and a blue component in one color pixel (dot) in order, and thus should be referred to as sub-pixel circuits in a strict sense, but will be referred to as the pixel circuit in the present description for convenience.

In FIG. 2, the control circuit 20 controls each unit based on video data Vid and a control signal Ctrl supplied from the host device.

The video data Vid is supplied in synchronization with a synchronization signal, and designates a grayscale level of a pixel in a video image to be displayed by the electro-optical device 10 by 8 bits for RGB, for example. The synchronization signal includes a vertical synchronization signal instructing a start of vertical scanning of the video data Vid, a horizontal synchronization signal instructing a start of horizontal scanning, and a dot clock signal indicating a timing of one pixel of the video data Vid.

In order to control each unit, the control circuit 20 generates, as logic signals, control signals Gref, Gcp, /Drst, /Gorst, /Gini, L_Ctr, and Sel(1) to Sel(1920) and a clock signal Clk. The control circuit 20 controls the scanning line drive circuit 120 based on the vertical synchronization signal contained in the control signal Ctrl.

The prefix “/” in the sign of the signal represents that the signal is negative logic.

Although omitted in FIG. 2, the control circuit 20 outputs a control signal/Gcp having a logical inversion relationship with the control signal Gcp, a control signal/Gref having a logical inversion relationship with the control signal Gref, and control signals/Sel(1) to/Sel(1920) having a logical inversion relationship with the Sel(1) to Sel(1920).

In the present description, a voltage refers to a potential difference between two points, but unless otherwise specified, an L level, which is a ground potential, is used as a reference. That is, the L level of the logic signal is 0 V. The H level of the logic signal is, for example, 6.0 V.

Control signals/Gel(1) to/Gel(540)) to be described later take three levels: L level, H level and M level. The M level is an intermediate level between the L level and the H level, and is a voltage of, for example, about 4 V to 5 V.

The scanning line drive circuit 120 is a circuit for driving the pixel circuits 110 arranged in a matrix in units of one row, and outputs, in addition to a scanning signal, various control signals synchronized with the scanning signal, which are omitted in FIG. 3.

The data signal output circuit 30 outputs a data signal toward the data line 14. Specifically, the data signal output circuit 30 outputs a data signal of a voltage according to the gradation level of each pixel constituting the video image.

In the embodiment, a voltage amplitude of the data signal output from the data signal output circuit 30 is compressed and supplied to the data line 14. Therefore, the compressed data signal also has a voltage according to the grayscale level of the pixel.

The data signal output circuit 30 also has a function of parallel-converting serially supplied video data Vdat into a plurality of phases (in this example, “6” phases corresponding to the number of columns of the data lines 14 forming the group) and outputting the converted data. For the sake of simplicity, the following description will be given as “6” phase.

The data signal output circuit 30 includes a shift register 31, a latch circuit 32, a D/A conversion circuit group 33, and an amplifier group 34.

The shift register 31 sequentially transfers the serially supplied video data Vdat in synchronization with the clock signal Clk, and stores the video data for one row, that is, 11,520 pixel circuits 110. In the embodiment, the shift register 31 sequentially stores the video data Vdat in units of six phases (in units of six pixels) in order to parallel-convert the video data Vdat into six phases and output the converted data.

The latch circuit 32 latches the video data Vdat stored in the shift register 31 in units of six phases in accordance with the control signal L_Ctr, parallel-converts the latched video data Vdat into six phases in accordance with the control signal L_Ctr, and outputs the converted data.

The D/A conversion circuit group 33 includes six digital to analog (D/A) converters. The six D/A converters convert the six-phase video data Vdat output from the latch circuit 32 into analog signals.

The amplifier group 34 includes six amplifiers. Six-phase analog signals output from the D/A conversion circuit group 33 are amplified by the six amplifiers and output as data signals Vd(1) to Vd(6).

Note that the D/A conversion circuit may be configured, for example, such that a switch and a capacitive element may be provided corresponding to each bit, and charging and discharging of the capacitive element may be controlled by the switch according to “O” or “1” of each bit. Depending on a configuration of the data signal output circuit 30, the amplifier group 34 does not necessarily have to be provided. For example, when the D/A conversion circuit is configured such that the switch and the capacitive element are provided corresponding to each bit and the charging and discharging of the capacitive element is controlled by the switch according to each bit, the amplifier group 34 may not be provided.

The control circuit 20 outputs the control signals Sel(1) to Sel(1920) that are sequentially and exclusively set at the H level during a compensation period preceding a write period, as will be described later.

In FIG. 3, the scanning line drive circuit 120 supplies scanning signals/Gwr(1), /Gwr(2), . . . , /Gwr(539),/Gwr(540)) to the scanning lines 12 in the 1st, 2nd, 3rd, . . . 539-th, and 540-th rows in this order.

In the electro-optical device 10, data transfer lines 14a are provided in one-to-one correspondence with the data lines 14.

The switch group 40 is a collection of transmission gates 45 provided for each data transfer line 14a.

Input terminals of the 1,920 transmission gates 45 corresponding to the data transfer lines 14a in the first, seventh, . . . , 11515-th columns, that is, (6j-5)-th columns are commonly coupled. The data signal Vd(1) is supplied to the input terminal in time series for each pixel.

Similarly, input terminals of the 1,920 transmission gates 45 corresponding to the data transfer lines 14a in the second, eighth, . . . , 11516-th columns, that is, (6j-4)-th columns are commonly coupled, and the data signal Vd(2) is supplied in time series for each pixel. Similarly, input terminals of the 1920 transmission gates 45 corresponding to the data transfer lines 14a in (6j-3)-th, (6j-2)-th, (6j-1)-th, and (6j)-th columns are commonly coupled, and the data signals Vd(3), Vd(4), Vd(5), and Vd(6) are sequentially supplied in time series for each pixel.

An output terminal of the transmission gate 45 in a certain column is coupled to one end of the data transfer line 14a in that column.

The six transmission gates 45 corresponding to columns (6j-5) to (6j) belonging to the j-th group are turned on between the input terminal and the output terminal when a control signal Sel(j) is at the H level (when the control signal/Sel(j) is at the L level).

In FIG. 3, only a part of the first group and the 960-th group is illustrated and other groups are omitted due to a space limitation. The transmission gate 45 in FIG. 3 is simply represented as a switch in FIG. 2.

In the present description, the “on state” of the switch, the transistor, or the transmission gate means that both ends of the switch, a source node and a drain node of the transistor, and both ends of the transmission gate are electrically coupled to each other to be in a low impedance state. The “off state” of the switch, the transistor, or the transmission gate means that both ends of the switch, the source node and the drain node of the transistor, or both ends of the transmission gate are not electrically coupled to be in a high impedance state.

In the present description, the “electrically coupled” or simply “coupled” means a direct or indirect connection or coupling between two or more elements.

The capacitive element group 50 is a collection of capacitive elements 51 provided for each data transfer line 14a. Here, one end of a capacitive element 41 corresponding to the data transfer line 14a in a certain column is coupled to one end of the data transfer line 14a in that column, and the other end of the capacitive element 41 is grounded to a constant potential, for example, a reference potential (L level) at a voltage zero.

The auxiliary circuit 70 is a collection of transmission gates 72 and 73 provided for each column, and capacitive elements 74 and 75 provided for each column.

Here, the transmission gate 72 corresponding to a certain column is turned on between the input terminal and the output terminal when the control signal Gcp is at the H level (when the control signal/Gcp is at the L level). An input terminal of the transmission gate 72 corresponding to a certain column is coupled to the other end of the data transfer line 14a in that column, and an output terminal of the transmission gate 72 corresponding to that column is coupled to an output terminal of the transmission gate 73 corresponding to that column, one end of the capacitive element 74 corresponding to that column, and one end of the capacitive element 75 corresponding to that column.

The transmission gate 73 corresponding to a certain column is turned on between the input terminal and the output terminal when the control signal Gref is at the H level (when the control signal/Gref is at the L level). A voltage Vref is applied to the input terminal of the transmission gate 73 corresponding to a certain column.

The other end of the capacitive element 75 corresponding to a certain column is grounded to a constant potential, for example, the reference potential at the voltage zero.

The other end of the capacitive element 74 corresponding to a certain column is coupled to one end of the data line 14 corresponding to that column.

The initialization circuit 60 is an aggregate of P-channel MOS type transistors 66, 67 and 68 provided for each data line 14.

The control signal/Drst is supplied to a gate electrode of the transistor 66 corresponding to the data line 14 in a certain column, a voltage Vel is applied to a source node of the transistor 66, and a drain node of the transistor 66 is coupled to the data line 14 in that column.

The control signal/Gorst is supplied to a gate electrode of the transistor 67 corresponding to the data line 14 in a certain column, a voltage Vorst is applied to a source node of the transistor 67, and a drain node of the transistor 67 is coupled to the data line 14 in that column.

The control signal/Gini is supplied to a gate electrode of the transistor 68 corresponding to the data line 14 in a certain column, a voltage Vini is applied to a source node of the transistor 68, and a drain node of the transistor 68 is coupled to the data line 14 in that column.

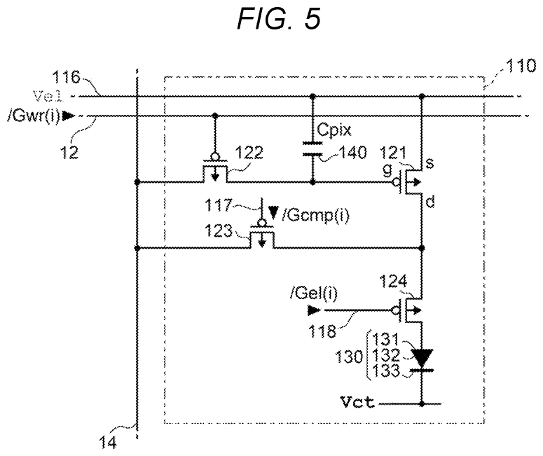

FIG. 5 is a diagram illustrating a configuration of the pixel circuit 110. The configurations of the pixel circuits 110R1, 110R2, 110G1, 110G2, 110B1, and 110B2 are the same as each other from an electrical point of view. Therefore, the pixel circuits 110 will be described by using the pixel circuit 110 corresponding to the i-th row and the (6j-5)-th column as a representative.

The pixel circuit 110 includes P-channel MOS type transistors 121 to 124, an OLED 130, and a capacitive element 140.

In addition to a scanning signal/Gwr(i), control signals/Gcmp(i) and/Gel(i) are supplied to the pixel circuits 110 in the i-th row from the scanning line drive circuit 120.

The OLED 130 is an example of the display element, and includes a pixel electrode 131, a common electrode 133 and a light emitting layer 132 sandwiched between the pixel electrode 131 and the common electrode 133. The pixel electrode 131 functions as an anode, and the common electrode 133 functions as a cathode. The pixel electrode 131 has light reflectivity, and the common electrode 133 has light reflectivity and light transmissivity. In the OLED 130, when a current flows from the anode to the cathode, holes injected from the anode and electrons injected from the cathode are recombined in the light emitting layer 132 to generate excitons, thereby generating white light.

In the case of color display as in the embodiment, the generated white light resonates in, for example, an optical resonator (not illustrated) including a reflective layer and a semi-reflective and semi-transmissive layer, and is emitted at a resonance wavelength set corresponding to any one of colors of red (R), green (G), and blue (B). A color filter corresponding to the color is provided on a light emission side of the optical resonator as described later. Therefore, light emitted from the OLED 130 is visually recognized by an observer through coloring by the optical resonator and the color filter.

When the electro-optical device 10 simply displays a monochrome image of only light and dark, the color filter is omitted.

In the transistor 121 of the pixel circuit 110 in the i-th row and (6j-5)-th column, a gate electrode g is coupled to a drain node of the transistor 122 and one end of the capacitive element 140, a source node s is coupled to an interconnection 116 of the voltage Vel at a high potential side of the power supply, and a drain node d is coupled to a source node of the transistor 123 and a source node of the transistor 124.

The other end of the capacitive element 140 is coupled to the interconnection 116. Therefore, the capacitive element 140 holds a voltage between the gate electrode g and the source node s in the transistor 121.

Note that the capacitive element 140 is formed by sandwiching an insulating film between electrodes in different interconnection layers on a semiconductor substrate as described later, but a parasitic capacitance in the gate electrode g of the transistor 121 may be used as the capacitive element 140.

In the transistor 122 of the pixel circuit 110 in the i-th row and (6j-5)-th column, a gate electrode is coupled to the scanning line 12 in the i-th row, and a source node is coupled to the data line 14 in the (6j-5)-th column.

In the transistor 123 of the pixel circuit 110 in the i-th row and (6j-5)-th column, the control signal/Gcmp(i) is supplied to a gate electrode, and a drain node is coupled to the data line 14 in the (6j-5)-th column. The control signal/Gcmp(i) is supplied from the scanning line drive circuit 120 via a control line 117 in the i-th row.

In the transistor 124 of the pixel circuit 110 in the i-th row and (6j-5)-th column, the control signal/Gel(i) is supplied to a gate electrode, and a drain node is coupled to the pixel electrode 131 which is an anode of the OLED 130. Note that the control signal/Gel(i) is supplied from the scanning line drive circuit 120 via a control line 118 in the i-th row.

The common electrode 133 functioning as a cathode of the OLED 130 is coupled to a power supply line of a voltage Vct. Since the electro-optical device 10 is formed on the semiconductor substrate, a substrate potential of the P-channel type transistors 121 to 124 is set to, for example, the voltage Vel.

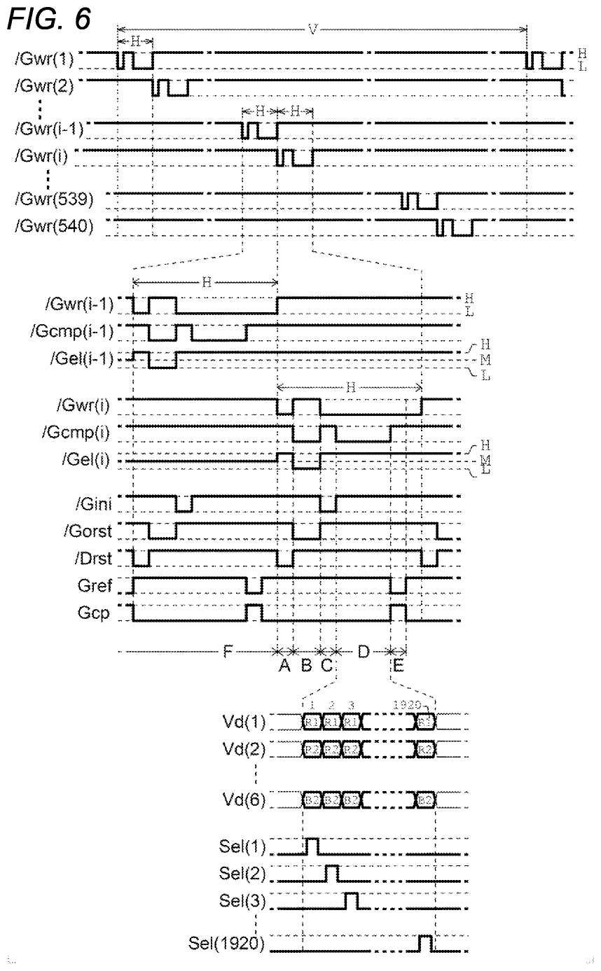

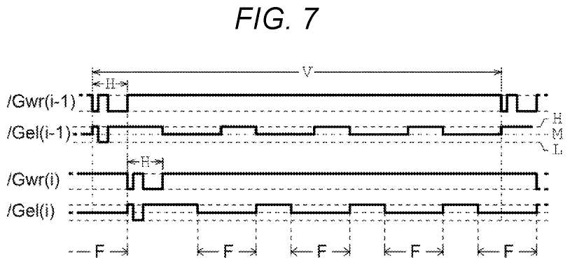

FIG. 6 is a timing chart illustrating an operation of the electro-optical device 10, and FIG. 7 is a diagram illustrating an example of a relationship between the scanning signal and the control signal for light emission.

In the electro-optical device 10, the first, second, third, . . . , 540-th rows are horizontally scanned in order in a period of one frame (V).

In the present description, the period of one frame (V) refers to a period required to display one frame of a video image designated by the video data Vid. For example, when a frequency of the vertical synchronization signal contained in a synchronization signal Sync is 60 Hz, a length of the period of one frame is 16.7 milliseconds corresponding to one cycle of the vertical synchronization signal. A period required for horizontal scanning of one row is a horizontal scanning period (H). In FIGS. 6 and 7, a vertical scale indicating a voltage is not always uniform for each signal.

An operation in the horizontal scanning period (H) in each row is almost the same in the pixel circuits 110. Operations of the pixel circuits 110 in the 1st to 11520-th columns in a row scanned in a certain horizontal scanning period (H) are also almost the same. Therefore, the following description focuses on the pixel circuit 110 in the i-th row and (6j-5)-th column and describes about them.

In the electro-optical device 10, the horizontal scanning period (H) is divided into five periods of initialization periods (A), (B), and (C), a compensation period (D), and a write period (E) in order of time. As the operation of the pixel circuit 110, a light emission period (F) is further added to the above-described five periods. The light emission period (F) in the i-th row is a period in which the control signal/Gel(i) is at the M level in FIG. 7.

Among the initialization periods (A), (B), and (C), the initialization period (A) is a period for setting the transistor 121 to an off state, and is a period for preliminary preparation processing of the initialization period (C). The initialization period (B) is a period for resetting a potential at the anode of the OLED 130, and the initialization period (C) is a period for applying, to the gate electrode g of the transistor 121, a voltage for turning on the transistor 121 at the start of the compensation period (E).

In the initialization period (A) in the horizontal scanning period (H), the control signal/Gini is at the H level, the control signal/Gorst is at the H level, the control signal/Drst is at the L level, the control signal Gref is at the H level, and the control signal Gcp is at the L level. Therefore, the transistor 68 is turned off, the transistor 67 is turned off, the transistor 66 is turned on, the transmission gate 73 is turned on, and the transmission gate 72 is turned off.

In the initialization period (A) of the horizontal scanning period (H) in which the i-th row is selected, the scanning signal/Gwr (i) is at the L level, the control signal/Gcmp(i) is at the H level, and the control signal/Gel(i) is at the H level. Therefore, in the pixel circuit 110, the transistor 122 is turned on, and the transistors 123 and 124 are turned off.

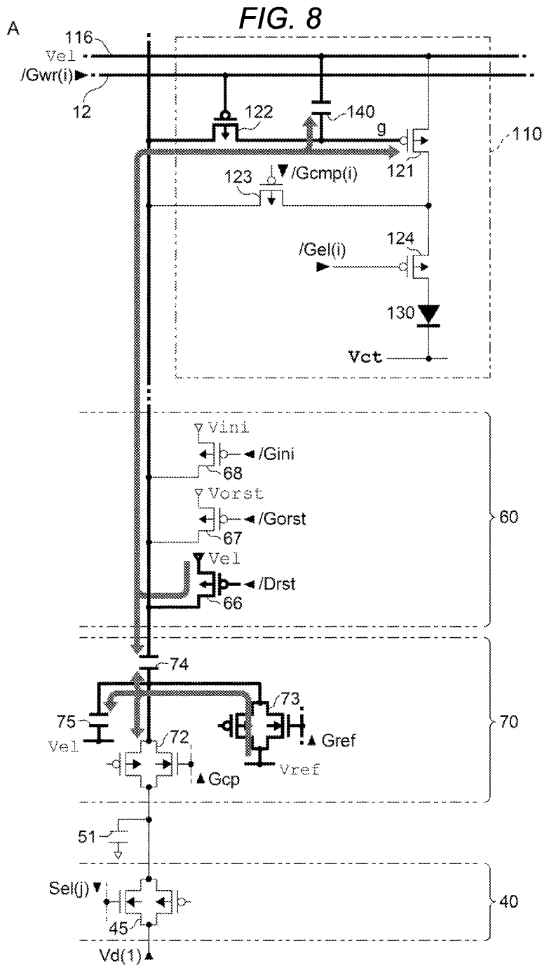

Therefore, in the initialization period (A), as illustrated in FIG. 8, the voltage Vref is applied to one end of the capacitive element 74, one end of the capacitive element 75, and the output terminal of the transmission gate 72 via the transmission gate 73. In the pixel circuit 110, the voltage Vel is applied to one end of the capacitive element 140 and the gate electrode g of the transistor 121 via the transistor 66, the data line 14, and the transistor 122 in order. When the voltage Vel is applied to the gate electrode g, a voltage between the gate electrode g and the source node s becomes zero, and thus the transistor 121 is forcibly in the off state, and a current flowing through the OLED 130 is cut off. The voltage Vel is applied to the other end of the capacitive element 74 via the data line 14, and thus the capacitive element 74 is charged to a voltage |Vel-Vref|.

In the initialization period (B) in the horizontal scanning period (H), the control signal/Gini is at the H level, the control signal/Gorst is at the L level, the control signal/Drst is at the H level, the control signal Gref is at the H level, and the control signal Gcp is at the L level. Therefore, the transistor 68 is kept off, the transistor 67 is turned on, the transistor 66 is turned off, the transmission gate 73 is kept on, and the transmission gate 72 is kept off.

In the initialization period (B) of the horizontal scanning period (H) in which the i-th row is selected, the scanning signal/Gwr (i) is at the H level, the control signal/Gcmp (i) is at the L level, and the control signal/Gel (i) is at the L level. Therefore, in the pixel circuit 110, the transistor 122 is turned off, and the transistors 123 and 124 are turned on.

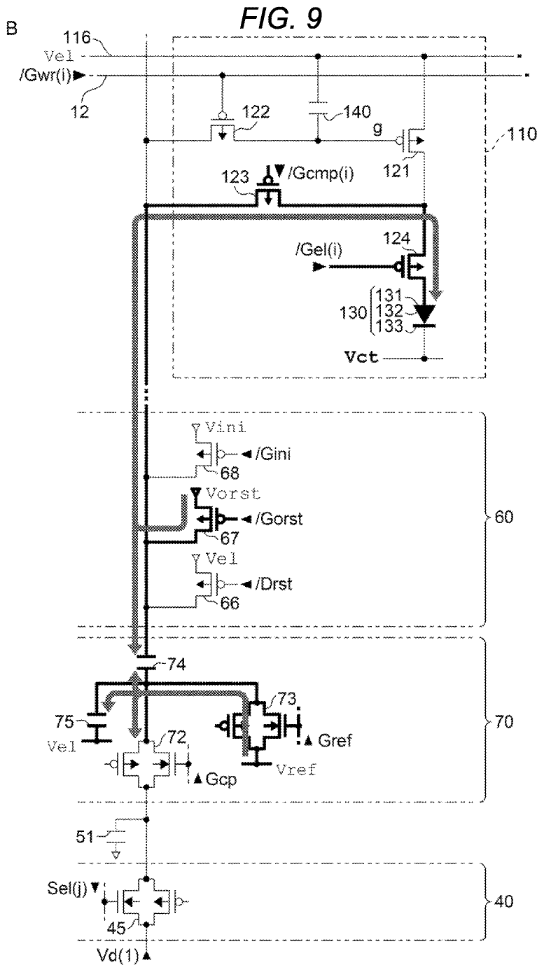

Therefore, in the initialization period (B), as illustrated in FIG. 9, one end of the capacitive element 74, one end of the capacitive element 75, and the output terminal of the transmission gate 72 are maintained at the voltage Vref. In the pixel circuit 110, the voltage Vorst is applied to the pixel electrode 131, which is the anode of the OLED 130, via the transistor 67, the data line 14, and the transistors 123 and 124 in order. In the OLED 130, the light emitting layer 132 is sandwiched between the pixel electrode 131 and the common electrode 133, and thus a capacitance component is parasitic. In the initialization period (B), by applying the voltage Vorst to the pixel electrode 131, a voltage retained in the capacitance component, specifically, a voltage according to the current flowing through the OLED 130 in the light emission period (F) is reset. Note that the voltage Vorst is a voltage that causes the OLED 130 to emit no light, and specifically, is a zero volt corresponding to the L level or a voltage (0 to 1 volts) close to the zero volt. The voltage Vorst is applied to the other end of the capacitive element 74 via the data line 14, and thus the capacitive element 74 is charged to a voltage |Vorst-Vref|.

In the initialization period (C) in the horizontal scanning period (H), the control signal/Gini is at the L level, the control signal/Gorst is at the H level, the control signal/Drst is at the H level, the control signal Gref is at the H level, and the control signal Gcp is at the L level. Therefore, the transistor 68 is turned on, the transistor 67 is turned off, the transistor 66 is kept off, the transmission gate 73 is kept on, and the transmission gate 72 is kept off.

In the initialization period (C) of the horizontal scanning period (H) in which the i-th row is selected, the scanning signal/Gwr(i) is at the L level, the control signal/Gcmp (i) is at the H level, and the control signal/Gel(i) is at the H level. Therefore, in the pixel circuit 110, the transistor 122 is turned on, and the transistors 123 and 124 are turned off.

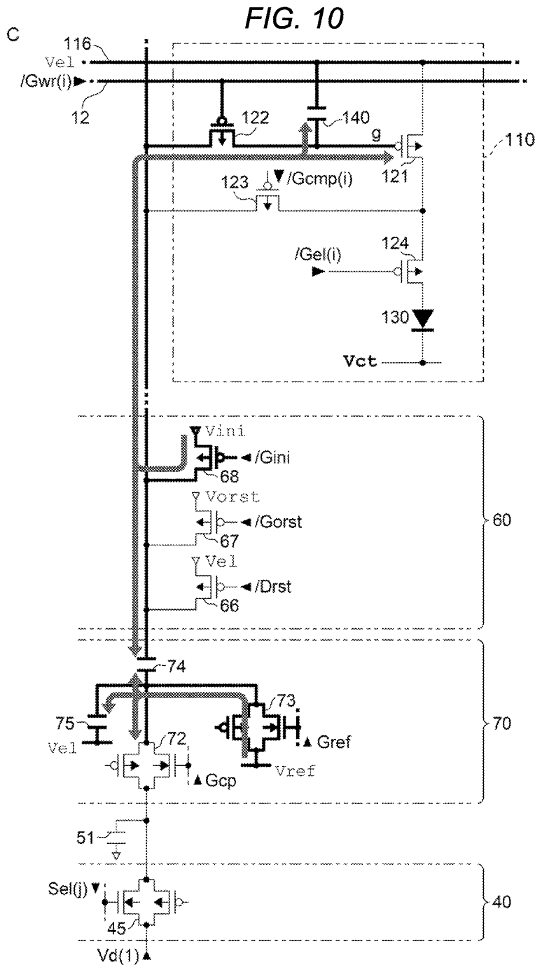

Therefore, in the initialization period (C), as illustrated in FIG. 10, one end of the capacitive element 74, one end of the capacitive element 75, and the output terminal of the transmission gate 72 are maintained at the voltage Vref. In the pixel circuit 110, the voltage Vini is applied to one end of the capacitive element 140 and the gate electrode g of the transistor 121 via the transistor 68, the data line 14, and the transistor 122 in order. The voltage Vini is applied to the other end of the capacitive element 74 via the data line 14, and thus the capacitive element 74 is charged to a voltage |Vini-Vref|.

In the compensation period (D) in the horizontal scanning period (H), the control signal/Gini is at the H level, the control signal/Gorst is at the H level, the control signal/Drst is at the H level, the control signal Gref is at the H level, and the control signal Gcp is at the L level. Therefore, the transistor 68 is turned off, the transistor 67 is kept off, the transistor 66 is kept off, the transmission gate 73 is kept on, and the transmission gate 72 is kept off.

In the compensation period (D) of the horizontal scanning period (H) in which the i-th row is selected, the scanning signal/Gwr(i) maintains at the L level, the control signal/Gcmp(i) changes to the L level, and the control signal/Gel(i) maintains at the H level. Therefore, in the pixel circuit 110, the transistor 122 is kept on, the transistor 123 is turned on, and the transistor 124 is turned off.

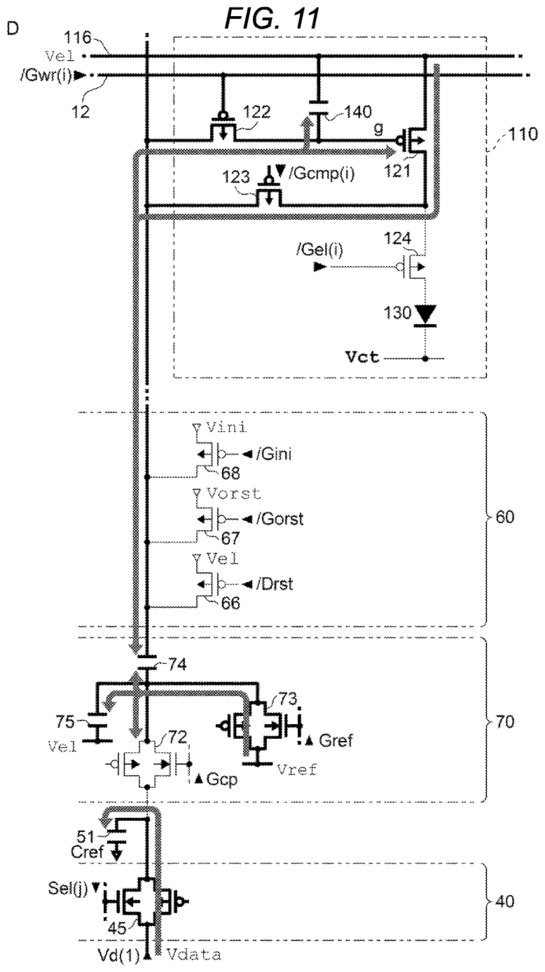

Therefore, in the compensation period (D), as illustrated in FIG. 11, one end of the capacitive element 74, one end of the capacitive element 75, and the output terminal of the transmission gate 72 are maintained at the voltage Vref.

In the pixel circuit 110, one end of the capacitive element 140 is retained at the voltage Vini in the immediately preceding initialization period (C), (Vel-Vini) is retained as a voltage between the gate electrode g and the source node s of the transistor 121.

In this state, when the transistor 123 is turned on, the transistor 121 is in a state in which the gate electrode g and the drain node d are coupled, that is, a diode-coupled state. Therefore, in the transistor 121, a voltage Vgs between the gate electrode g and the source node s converges to approach a threshold voltage of the transistor 121. Here, when the threshold voltage is represented as Vth for convenience, the gate electrode g of the transistor 121 converges to approach a voltage (Vel-Vth) corresponding to the threshold voltage Vth.

Note that at the start of the compensation period (D), it is necessary that a current flows from the source node s to the drain node d in the diode-coupled transistor 121. Therefore, the voltage Vini applied to the gate electrode g in the initialization period (C) before the compensation period (D) has a relationship Vini<Vel-Vth.

In the compensation period (D), the gate electrode g of the transistor 121 is coupled to the data line 14 via the transistor 122, and the drain node d of the transistor 121 is coupled to the data line 14 via the transistor 123. Therefore, the data line 14 and the other end of the capacitive element 74 also converge to approach the voltage (Vel-Vth). Therefore, the capacitive element 74 is charged to substantially a voltage |Vel-Vth-Vref|.

On the other hand, in the compensation period (D), the control signals Sel(1) to Sel(1920) are sequentially and exclusively set at the H level. Although omitted in FIG. 5, in the compensation period (D), the control signals/Sel(1) to/Sel(1920) are sequentially and exclusively set at the L level in synchronization with control signals Sel(1) to Sel(1920).

For example, when the control signal Sel(j) among the control signals Sel(1) to Sel(1920) is at the H level, the data signal output circuit 30 outputs, as the data signals Vd(1) to Vd(6), two dots of color components expressed by the six pixel circuits 110 corresponding to intersections between the scanning line 12 in the i-th row and the data lines 14 belonging to the j-th group.

For example, in a period in which the control signal Sel(j) is at the H level, the data signal output circuit 30 outputs, as the data signal Vd(1), the R component expressed by the pixel circuit 110R1 in the i-th row and (6j-5)-th column. For example, the B component expressed by the pixel circuit 110B2 in the i-th row and (6j)-th column is output as the data signal Vd(6).

When the control signals Sel(1) to Sel(1920) are sequentially and exclusively set at the H level, voltages of the data signals corresponding to respective pixels are retained in the capacitive elements 51 corresponding to the first to 11520-th columns.

FIG. 10 illustrates a state in which the control signal Sel(j) corresponding to the j-th group to which the pixel circuit 110 belongs is at the H level in the compensation period (D) and a voltage Vdata of the data signal Vd(1) is retained in the capacitive element 51.

In the write period (E) in the horizontal scanning period (H), the control signal/Gini is at the H level, the control signal/Gorst is at the H level, the control signal/Drst is at the H level, the control signal Gref is at the L level, and the control signal Gcp is at the H level. Therefore, the transistors 68, 67, and 66 are kept off, the transmission gate 73 is turned off, and the transmission gate 72 is turned on. In the write period (E) of the horizontal scanning period (H) in which the i-th row is selected, the scanning signal/Gwr(i) maintains at the L level, the control signal/Gcmp(i) changes to the H level, and the control signal/Gel(i) maintains at the H level. Therefore, in the pixel circuit 110, the transistor 122 is turned on, and the transistors 123 and 124 are turned off.

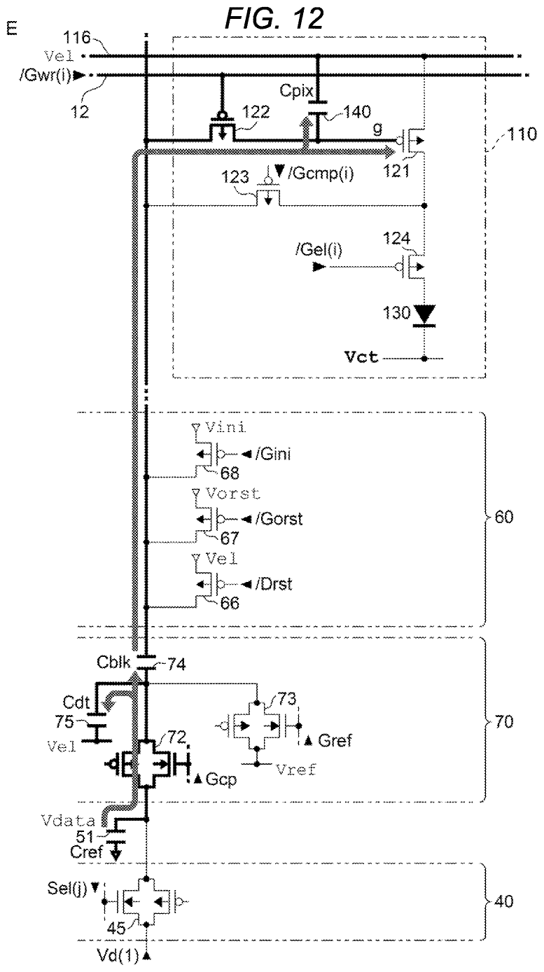

Therefore, in the write period (E) of the horizontal scanning period (H) in which the i-th row is selected, as illustrated in FIG. 12, when the transmission gate 73 is turned off and the transmission gate 72 is turned on, one end of the capacitive element 74 changes from the voltage Vref according to the voltage retained in the capacitive element 51. The voltage variation propagates to the gate electrode g via the capacitive element 74, the data line 14, and the transistor 122 in order. The voltage of the gate electrode g after the change is retained in the capacitive element 140.

As illustrated in FIG. 12, capacitance of the capacitive element 51 is denoted by Cref, a capacitance size of the capacitive element 74 is denoted by Cblk, a capacitance size of the capacitive element 75 is denoted by Cdt, and a capacitance size of the capacitive element 140 is denoted by Cpix. The voltage of the data signal Vd(1) that is retained in the capacitive element 51 in the compensation period (D) is denoted by Vdata.

A voltage variation ΔV of the gate electrode g from the compensation period (D) to the write period (E) is expressed by the following formula (1).

$$\begin{matrix}ΔV = \frac{\frac{Cblk ( Cdt + Cpix )}{Cblk + Cdt + Cpix} \times Vref + Cref \times Vdata}{\frac{Cblk ( Cdt + Cpix )}{Cblk + Cdt + Cpix} \times ( Vdata - Vref )} - Vref \\ = \frac{Cref}{\frac{Cblk ( Cdt + Cpix )}{Cblk + Cdt + Cpix}} \times ( Vdata - Vref ) \\ = Ka \times ( Vdata - Vref )\end{matrix} \qquad ( 1 )$$

That is, as illustrated in the formula (1), the gate electrode g changes to a value obtained by multiplying a voltage variation amount (Vdata-Vref) at one end of the capacitive element 74 by a coefficient Ka. The coefficient Ka is a coefficient less than “1” and is determined by the capacitance sizes Cref, Cblk, Cdt, and Cpix. In other words, the capacitance sizes Cref, Cblk, Cdt, and Cpix are designed to be appropriate values, and the coefficient Ka is set to be less than “1”. When the coefficient Ka is less than “1”, a voltage amplitude from the lowest value to the highest value of the voltage Vdata of the data signal is compressed according to the coefficient Ka and propagates to the gate electrode g.

When the pixel circuit 110 is miniaturized, the current flowing through the OLED 130 may greatly change with respect to a slight change in voltage Vgs between the gate electrode g and the source node s in the transistor 121.

Even in this case, in the embodiment, the voltage amplitude of the voltage Vdata of the data signal is compressed according to the coefficient Ka and propagates to the gate electrode g, and thus the current flowing through the OLED 130 can be accurately controlled.

After the write period (E) ends, the light emission period (F) starts. In the embodiment, from the horizontal scanning period (H) in which the i-th row is selected until the horizontal scanning period (H) in which the i-th row is selected again after a period of one frame (V) elapses, the light emission period (F) of the i-th row occurs, for example, four times, as illustrated in FIG. 7. Specifically, after the horizontal scanning period (H) in which the i-th row is selected, the light emission period (F) in which the control signal/Gel(i) is at the M level occurs four times at substantially equal intervals, and a time length of the period in which the control signal/Gel(i) is at the M level is also set to substantially the same length.

Note that from the horizontal scanning period (H) in which the i-th row is selected until the horizontal scanning period (H) in which the i-th row is selected again after the period of one frame (V) elapses, the light emission period (F) of the i-th row may be continued, that is, the control signal/Gel(i) may be continued at the M level.

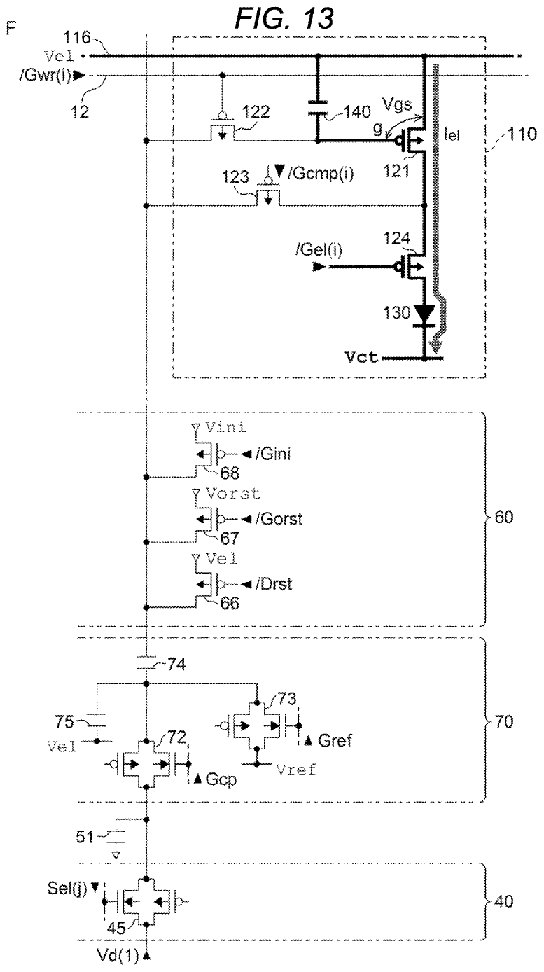

When the control signal/Gel(i) is at the M level in the light emission period (F), as illustrated in FIG. 13, the transistor 121 causes a current Iel according to the voltage Vgs to flow through the OLED 130, the current Iel being limited by resistance between the source node and the drain node of the transistor 124. Therefore, the OLED 130 emits light at a luminance according to the current Iel.

In FIGS. 8 to 13, only the capacitive element 51 out of the capacitive element group 50 is illustrated.

In the embodiment, the amplitude of the voltage Vdata of the data signal output from the data signal output circuit 30 is compressed via the capacitive element 74 and is supplied to the gate electrode g in the pixel circuit 110 as the data signal.

On the other hand, in the compensation period (D), the threshold voltage Vth of the transistor 121 is compensated.

Next, usefulness of the compensation period (D) will be described. In the description of the usefulness, in order to avoid complication of the formula, it is assumed that a compression ratio of the voltage Vdata of the data signal is “1”, that is, the voltage Vdata of the data signal is supplied to the data line 14 as it is in the write period (E) after the compensation period (D). It is assumed that in the light emission period (F), not the M level but the L level is applied to the gate electrode of the transistor 124, the transistor 124 is turned on, and the resistance between the source node and the drain node is ideally zero.

First, the current Iel flowing through the OLED 130 in the light emission period (F) can be expressed by the following formula (2).

$$Iel = {{k}_{1} ( Vgs - Vth )}^{2} \qquad ( 2 )$$

A coefficient k1 in the formula (2) is expressed by the following formula (3).

$${k}_{1} = ( W / 2 L ) \cdot μ Cox \qquad ( 3 )$$

In the formula (3), W is a channel width of the transistor 121, L is a channel length of the transistor 121, μ is a mobility of carriers, and Cox is capacitance of a (gate) oxide film per unit area in the transistor 121.

In a configuration in which the voltage Vdata of the data signal is not compressed and the threshold voltage of the transistor 121 is not compensated, when the voltage Vdata of the data signal is directly applied to the gate electrode g of the transistor 121, the voltage Vgs between the gate electrode g and the source node s in the transistor 121 can be expressed as in the following formula (4).

$$Vgs = \vert Vel - Vdata \vert \qquad ( 4 )$$

At this time, the current Iel flowing through the OLED 130 can be expressed by the following formula (5).

$$\begin{matrix}Iel = {{k}_{1} ( Vgs - Vth )}^{2} \\ = {{k}_{1} ( Vel - Vdata - Vth )}^{2}\end{matrix} \qquad ( 5 )$$

As represented by the formula (5), the current Iel is affected by the threshold voltage Vth. Here, due to a semiconductor process, a variation in threshold voltage Vth in the transistor 121 is in a range of several mV to several tens of mV. When the threshold voltage Vth in the transistor 121 varies in a range of several mV to several tens of mV, the current Iel may cause a difference of 40% at the maximum between the adjacent pixel circuits 110.

Current-luminance characteristics of the OLED 130 are substantially linear. Therefore, in the configuration in which the threshold voltage Vth is not compensated, even when data signals of the same voltage Vdata are supplied to the two pixel circuits 110 in order to cause two OLEDs 130 to emit light with the same luminance, the currents actually flowing through the OLEDs 130 are different. Therefore, in the configuration in which the threshold voltage Vth is not compensated, the luminance varies, and the display quality is greatly impaired.

In the compensation period (D), when the gate electrode g in the transistor 121 is converged to approach the voltage (Vel-Vth) and then is changed to the voltage Vdata, the voltage Vgs between the gate electrode g and the source node s in the transistor 121 can be expressed as the following formula (6).

$$Vgs = Vth - {k}_{2} ( Vdata - Vref ) \qquad ( 6 )$$

A coefficient k2 in the formula (6) is a coefficient determined by the capacitance sizes Cblk and Cpix in a configuration in which the voltage Vdata of the data signal is not compressed (a configuration in which the capacitive element 74 is not provided).

When the voltage Vgs is expressed as in the formula (6), the current Iel flowing through the OLED 130 can be expressed as in the following formula (7).

$$\begin{matrix}Iel = {k}_{1} {\{ Vth - {k}_{2} ( Vdata - Vref ) - Vth \}}^{2} \\ = {k}_{1} {{k}_{2} ( Vref - Vdata )}^{2}\end{matrix} \qquad ( 7 )$$

In the formula (7), a term of the threshold voltage Vth is removed, and the current Iel is determined by the voltage Vdata of the data signal. Accordingly, deterioration in display quality due to the threshold voltage Vth of the transistor 121 can be prevented.

In the embodiment, actually, as illustrated in the formula (1), the voltage amplitude from the lowest value to the highest value of the voltage Vdata of the data signal is compressed according to the coefficient Ka and propagates to the gate electrode g.

In the embodiment, the M level is supplied to the gate electrode of the transistor 124 in the light emission period (F), and the current Iel is limited, but there is no change in that the deterioration in display quality due to the threshold voltage Vth can be prevented.

Next, the usefulness of applying the M level to the gate electrode of the transistor 124 in the light emission period (F) in the embodiment will be described.

The reason for applying the M level to the gate electrode of the transistor 124 is to maintain the constant current characteristic of the transistor 121 regardless of the aging of the current-voltage characteristics of the OLED 130 by operating the transistor 124 in the saturation region.

Specifically, when the current Iel flows, the OLED 130 emits light at a luminance according to the current Iel. In the embodiment, in the pixel circuit 110, the voltage of the gate electrode g in the transistor 121 is retained by the capacitive element 140, and thus the constant current characteristic of the current Iel flowing from the interconnection 116 to the OLED 130 can be secured.

However, in the OLED 130, element characteristics change with the elapse of the light emission time, and a potential of the anode (pixel electrode 131) necessary for passing a constant current gradually increases. When the potential of the anode of the OLED 130 increases, an equilibrium point of the potential in a path from the interconnection 116 to the common electrode 133 changes, and a potential of the source node of the transistor 124, that is, the drain node d of the transistor 121 increases. When the potential of the drain node d of the transistor 121 increases, the voltage between the source node s and the drain node d in the transistor 121 also fluctuates, and the current flowing through the drain node of the transistor 121 also fluctuates, and as a result, the constant current characteristic of the OLED 130 is impaired.

Therefore, in the embodiment, the transistor 124 is operated in the saturation region as a countermeasure against the loss of the constant current characteristic due to aging of the element characteristics of the OLED 130.

When the transistor 124 is operated in the saturation region, even when the potential of the anode of the OLED 130 changes, the transistor 124 is directly affected by the change. The transistor 121 is affected by the potential fluctuation at the drain node of the transistor 124, but the fluctuation of the drain current in the saturation region is small. Therefore, the influence of the potential fluctuation of the drain node in the transistor 121 coupled to the transistor 124 and the potential fluctuation of the gate electrode due to the current leakage is alleviated.

In the array illustrated in FIG. 4, the size in the X direction of the pixel circuit 110 except the display element is ½ times the size in the X direction of the display element. Therefore, since the arrangement pitch of the data lines 14 is narrowed, in terms of one pixel circuit 110, it becomes easily to be affected by the voltage variation in the adjacent data lines 14. In particular, in the gate electrode g of the transistor 121, after the voltage according to the gradation level is held, the voltage variation in the adjacent data lines 14 propagates via the parasitic capacitance, and the voltage held therein is likely to fluctuate. Therefore, the structure of the pixel circuit 110 in which it is achieved to solve this point in the electro-optical device 10 according to the present embodiment will be described.

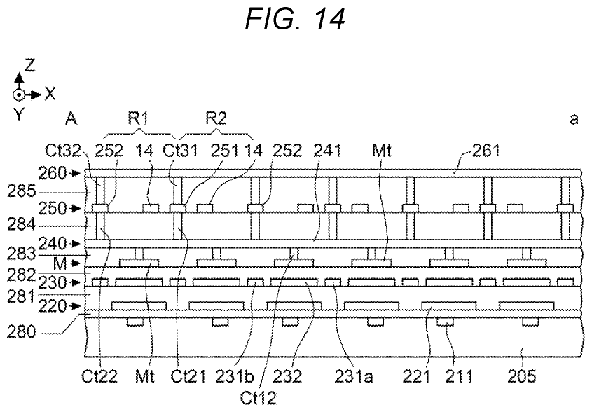

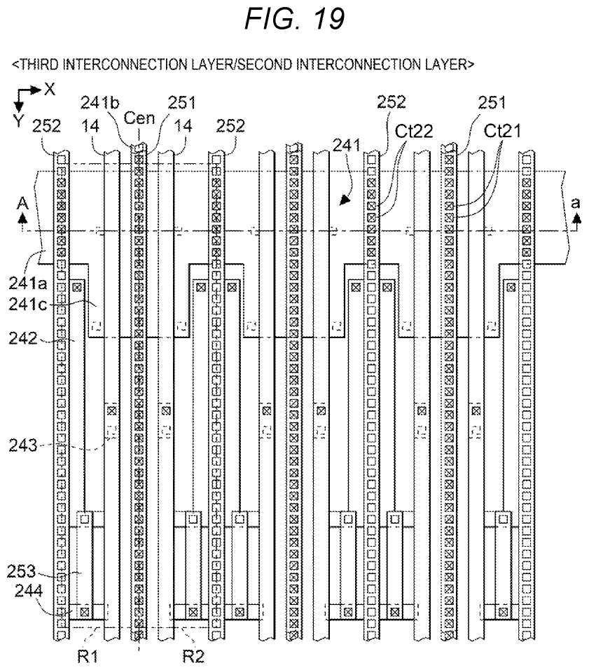

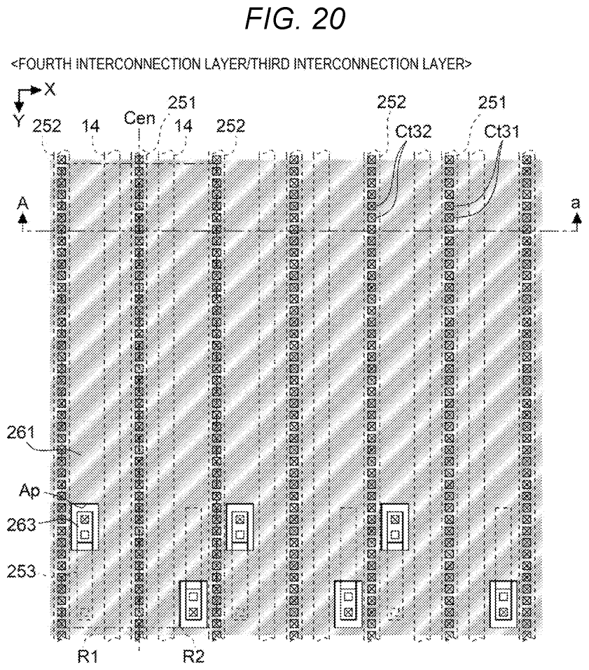

FIG. 14 is a cross-sectional view of an essential part of the electro-optical device 10, particularly, a cross-sectional view of the pixel circuit 110 illustrating a laminate structure of the interconnections and the transistors. Although details will be described later, FIG. 14 also serves as a cross-sectional view of the electro-optical device 10 taken along a line A-a in FIGS. 19 and 20.

In the semiconductor substrate constituting the electro-optical device 10, layers used as the conductive layers are a region 211, a gate electrode layer 220, a first interconnection layer 230, a capacitance electrode layer M, a second interconnection layer 240, the capacitance electrode layer M, a third interconnection layer 250, and a fourth interconnection layer 260 in order toward the Z direction.

A pixel electrode layer is provided after the fourth interconnection layer 260, but is omitted in FIG. 14.

The gate electrode layer 220 is, for example, polysilicon. For example, aluminum, an alloy containing aluminum, or copper is used as the first interconnection layer 230, the capacitance electrode layer M, the second interconnection layer 240, the third interconnection layer 250, and the fourth interconnection layer 260.

The pixel electrode layer is a laminate of a metal layer having reflectivity and a conductor layer having transmissivity and conductivity. As the metal layer having reflectivity, for example, aluminum or an alloy containing aluminum is used, and as the conductor layer having transmissivity and conductivity, for example, indium tin oxide is used.

Ordinal numbers (first, second, third, and fourth) of the interconnection layers in the detailed description of the disclosure indicate an order of film formation in the semiconductor substrate, whereas the ordinal numbers of the interconnection layers in the claims are used to distinguish the interconnection layers. Therefore, the ordinal numbers of the interconnection layers in the detailed description of the disclosure do not necessarily match the ordinal numbers of the interconnection layers in the claims.

The region 211 is a semiconductor region of the transistor. A gate insulating film 280 is disposed between the region 211 and the gate electrode layer 220. The gate electrode of the transistor is provided by patterning the gate electrode layer 220.

In FIG. 14, the region 211 in the transistor 121 and the electrode 221 as the gate of the transistor 121 are illustrated.

The first interconnection layer 230, the second interconnection layer 240, the third interconnection layer 250, and the fourth interconnection layer 260 are provided with interconnections, electrodes, and so on by patterning these layers. The capacitance electrode Mt serving as the other end of the capacitive element 140 is provided by patterning the capacitance electrode layer M.

A first interlayer insulating film 281 is disposed between the gate electrode layer 220 and the first interconnection layer 230. The electrode in the gate electrode layer 220 and the electrode, the interconnection, and so on in the first interconnection layer 230 are electrically coupled to each other with a contact hole penetrating the first interlayer insulating film 281.

The contact hole coupling two interconnections may be filled with the interconnection layer as an upper layer of the two interconnections or may be filled with a conductive material such as tungsten.

In the present description, in comparison with two certain interconnection layers, an upper layer refers to an interconnection or the like which is configured with an interconnection layer formed in a temporally posterior step and is located in the Z direction, and a lower layer refers to an interconnection or the like which is configured with an interconnection layer formed in a temporally anterior step and is located at the opposite side in the Z direction.

A second interlayer insulating film 282 is disposed between the first interconnection layer 230 and the capacitance electrode layer M.

A third interlayer insulating film 283 is disposed between the capacitance electrode layer M and the second interconnection layer 240.

Electrical coupling between the interconnection or the like formed of the first interconnection layer 230 and the interconnection or the like formed of the second interconnection layer 240 is achieved with a contact hole penetrating the second interlayer insulating film 282 and the third interlayer insulating film 283. Further, electrical coupling between the capacitance electrode Mt and the interconnection or the like formed of the second interconnection layer 240 is achieved with a contact hole Ct12 penetrating the third interlayer insulating film 283.

A fourth interlayer insulating film 284 is disposed between the second interconnection layer 240 and the third interconnection layer 250. Electrical coupling between the interconnection or the like formed of the second interconnection layer 240 and the interconnection or the like formed of the third interconnection layer 250 is achieved with a contact hole (e.g., Ct21, Ct22) penetrating the fourth interlayer insulating film 284.

A fifth interlayer insulating film 285 is disposed between the third interconnection layer 250 and the fourth interconnection layer 260. Electrical coupling between the interconnection or the like formed of the third interconnection layer 250 and the interconnection or the like formed of the fourth interconnection layer 260 is achieved with a contact hole (e.g., Ct31, Ct32) penetrating the fifth interlayer insulating film 285.

Although omitted in FIG. 14, electrical coupling between the interconnection or the like formed of the fourth interconnection layer 260 and the pixel electrode 131 formed of the pixel electrode layer is achieved with a contact hole penetrating an interlayer insulating film.

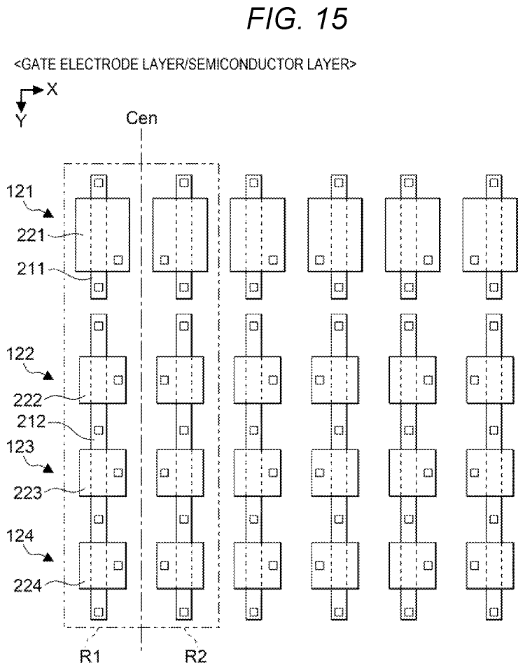

FIGS. 15 to 21 are plan views illustrating a specific interconnection structure in the electro-optical device 10.

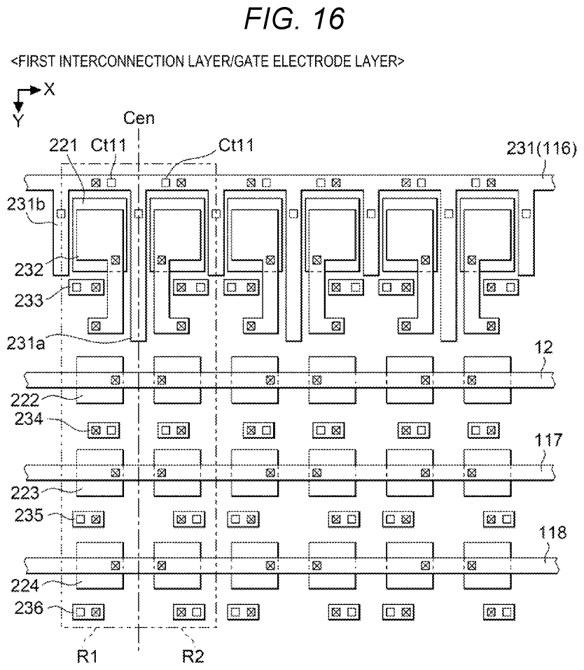

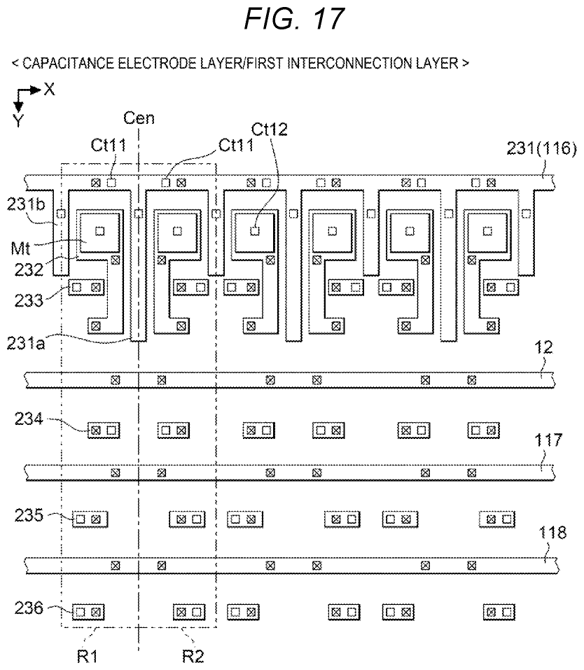

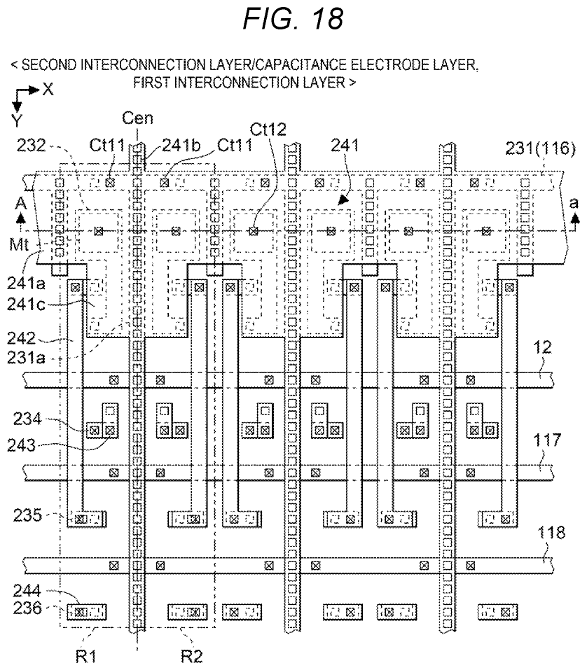

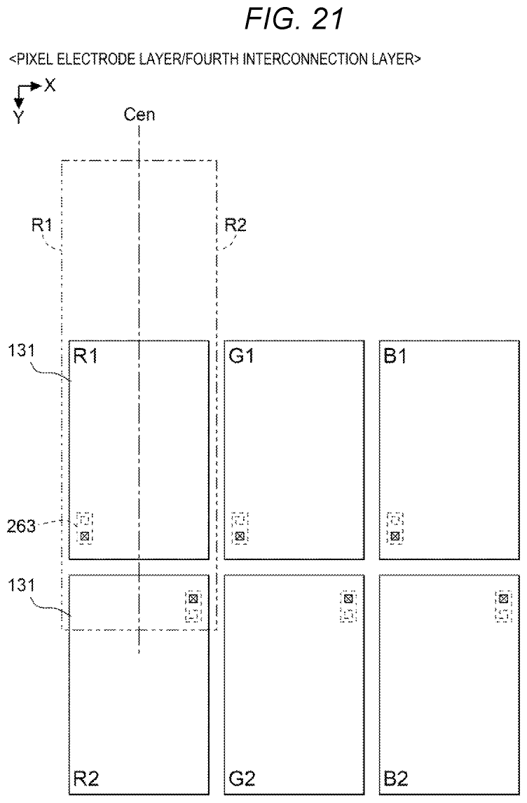

Specifically, FIG. 15 is a plan view illustrating a transistor region, an interconnection, and the like formed in the semiconductor layer 205, and the gate electrode and the like formed by patterning the gate electrode layer 220. FIG. 16 is a plan view illustrating the gate electrodes and the like formed by patterning the gate electrode layer 220 and the interconnections and the like formed by patterning the first interconnection layer 230. FIG. 17 is a plan view illustrating the interconnections and the like formed by patterning the first interconnection layer 230 and the capacitance electrodes Mt. FIG. 18 is a plan view illustrating the interconnections and the like formed by patterning the first interconnection layer 230, the capacitance electrodes Mt, and the interconnections and the like formed by patterning the second interconnection layer 240. FIG. 19 is a plan view illustrating the interconnections and the like by patterning the second interconnection layer 240 and the interconnections and the like by patterning the third interconnection layer 250. FIG. 20 is a plan view illustrating the interconnections and the like by patterning the third interconnection layer 250 and the interconnections and the like by patterning the fourth interconnection layer 260. FIG. 21 is a plan view illustrating the interconnections and the like by patterning the fourth interconnection layer 260 and the pixel electrodes 131.

In FIGS. 15 to 21, a simple square frame (without an x mark) indicates a position of an interconnection, an electrode, or the like in a lower layer of two interconnection layers coupled with the contact hole, and a square frame with the x mark indicates a position of an interconnection, an electrode, or the like in an upper layer of the two interconnection layers coupled with the contact hole.

As for the name of each unit, the interconnection layer is a layer that collectively refers to a conductive layer after film formation and before patterning, or an interconnect, an electrode, or the like having the same conductive layer before patterning. The . . . line, the . . . electrode, and a . . . relay interconnection are formed by patterning the interconnection layer, and include the scanning line 12, the data line 14, and the control lines 117 and 118.

In FIG. 15, the region 211 is a semiconductor region of the transistor 121. A region 212 is a common semiconductor region to the transistors 122 to 124.

An electrode 221 is a gate electrode of the transistor 121. In the drawing, a region where the electrode 221 and the region 211 overlap in plan view is a channel region of the transistor 121.

Similarly, an electrode 222 is a gate electrode of the transistor 122. A region where the electrode 222 and the region 212 overlap in plan view is a channel region of the transistor 122. An electrode 223 is a gate electrode of the transistor 123. A region where the electrode 223 and the region 212 overlap in plan view is a channel region of the transistor 123. An electrode 224 is a gate electrode of the transistor 124. A region where the electrode 224 and the region 212 overlap in plan view is a channel region of the transistor 124.

As illustrated in FIG. 15, for two adjacent pixel circuits of the same color along the X direction, the transistors 121 to 124 and the electrodes 221 to 224 within the two pixel circuits excluding the display elements are symmetrically disposed on the left and right with respect to an imaginary line Cen that partitions the two pixel circuits in plan view.

In the present description, a plan view means that the electro-optical device 10 is viewed from a direction opposite to the Z direction, and a cross-sectional view means that the semiconductor substrate is viewed by being broken in a direction perpendicular to the substrate surface.

As illustrated in FIG. 16, an interconnection 231, the scanning line 12, the control lines 117, 118, and the interconnections 232 to 236 are provided by patterning the first interconnection layer 230.

The interconnection 231, the scanning line 12, and the control lines 117 and 118 each extend in the X direction, and are provided in 540 rows according to the arrangement of the pixel circuits 110 excluding the display elements. In other words, the interconnection 231, the scanning line 12, and the control lines 117 and 118 are each commonly provided in the pixel circuits 110 in one row (11,520 pixel circuits 110).

The interconnection 231 is disposed along the X direction. The voltage Vel is directly or indirectly applied to the interconnection 231. Therefore, the interconnection 231 corresponds to the interconnection 116 in terms of FIG. 5. The interconnection 231 is coupled to the source node of the transistor 121 in the region 211 via the contact hole.

Indirectly applying a voltage to an interconnection formed of a certain interconnection layer means that the voltage at an interconnection formed of another interconnection layer is applied via the contact hole. Further, directly applying a voltage to an interconnection formed of a certain interconnection layer means that the interconnection extends to an outside of the display region 100, the voltage is applied at the outside, and is drawn to an inside of the display region 100.

The interconnection 232 is a relay interconnection for guiding the drain node of the transistor 122 to the gate electrode of the transistor 121. For this reason, in the region 212, the interconnection 232 is coupled to the drain node of the transistor 122 via a contact hole and is coupled to the electrode 221 via a contact hole.

In addition to a portion extending in the X direction, the interconnection 231 includes branch interconnections 231a and 231b that protrude in the Y direction and sandwich the electrode 221 on the left and right so as to include a boundary between the pixel circuits adjacent to each other in the X direction. Specifically, the branch interconnection 231a is provided to include the imaginary line Cen that partitions the two adjacent pixel circuits of the same color along the X direction, and the branch interconnection 231b is provided to include a partition line between two adjacent pixel circuits of different colors along the X direction.

Therefore, three sides of the interconnection 232 coupled to the gate electrode of the transistor 121 are shielded by the interconnection 231 including the branch interconnections 231a and 231b formed of the same first interconnection layer 230.

The interconnection 233 is a relay interconnection for guiding the drain node of the transistor 121 to the source node of the transistor 123 and the source node of the transistor 124. For this reason, the interconnection 233 is coupled to the drain node of the transistor 121 via a contact hole in the region 211.

The interconnection 234 is a relay interconnection for guiding the source node of the transistor 122 and the drain node of the transistor 123 to the data line 14. For this reason, in the region 212, the interconnection 234 is coupled to a node serving as both the drain node of the transistor 121 and the drain node of the transistor 123 via a contact hole.

The interconnection 235 is a relay interconnection for guiding an interconnection 242 of the second interconnection layer 240 described later to the source node of the transistor 123 and the source node of the transistor 124. For this reason, in the region 212, the interconnection 235 is coupled to a node serving as both the source node of the transistor 123 and the source node of the transistor 124 via a contact hole.

The interconnection 236 is a relay interconnection for guiding the drain node of the transistor 124 to the pixel electrode 131 which is the anode of the OLED 130. For this reason, the interconnection 236 is coupled to the drain of the transistor 124 via a contact hole in the region 212.

Note that the scanning line 12 extending in the X direction is coupled to the electrode 222 via a contact hole. Similarly, the control line 117 extending in the X direction is coupled to the electrode 223 via a contact hole, and the control line 118 extending in the X direction is coupled to the electrode 224 via a contact hole.

As illustrated in FIG. 16, the interconnections 231 to 236 in two pixel circuits which are the same in color, are adjacent along the X direction to each other, and exclude the display elements are symmetrically disposed with respect to the imaginary line Cen in plan view.

As illustrated in FIG. 17, the capacitance electrode Mt is disposed by patterning the capacitance electrode layer M so as to overlap the interconnection 232 in plan view.

Note that the capacitance electrodes Mt in two pixel circuits which are the same in color, are adjacent along the X direction to each other, and exclude the display elements are symmetrically disposed with respect to the imaginary line Cen in plan view.

As illustrated in FIG. 18, interconnections 241 to 244 are provided by patterning the second interconnection layer 240.

The interconnection 241 extends in the X and Y directions and is provided in a grid shape. Specifically, the interconnection 241 includes extending portions 241a extending in the X direction, extending portions 241b extending in the Y direction, and extension portions 241c each extended in the Y direction from a portion where the extending portions 241a and 241b intersect.

The voltage Vel is directly and indirectly applied to the interconnection 241. Therefore, in order to reduce the interconnection resistance of the interconnection 241, the extending portion 241a is wider in the Y direction than the scanning line 12 and the control lines 117 and 118 also extending in the X direction. The extending portion 241a overlaps the interconnections 231 so as to include the interconnections 231 in plan view.

The extending portion 241b extends along the imaginary line Cen so as to include the imaginary line Cen in plan view and is disposed so as to overlap the branch interconnection 231a in plan view.

The extension portion 241c overlaps the interconnection 232 together with the extending portion 241a so as to include the interconnection 232 in plan view.

The interconnection 241 is coupled to the interconnections 231 via contact holes Ct11, and is coupled to the capacitance electrodes Mt via the contact holes Ct12.

The interconnection 242 is a relay interconnection disposed along the Y direction, and is coupled to the interconnections 233 and 235 via respective contact holes. Therefore, the drain node of the transistor 121 is coupled to the source node of the transistor 123 and the source node of the transistor 124 via the interconnections 233, 241, and 235 in order.

The interconnection 243 is a relay interconnection for guiding the source node of the transistor 121 and the drain node of the transistor 123 to the data line 14. Therefore, the interconnection 243 is coupled to the interconnection 234 via a contact hole.

The interconnection 244 is a relay interconnection for guiding the drain node of the transistor 124 to the pixel electrode 131. Therefore, the interconnection 244 is coupled to the interconnection 236 via a contact hole.

As illustrated in FIG. 18, the interconnections 241 to 244 in two pixel circuits which are the same in color, are adjacent along the X direction to each other, and exclude the display elements are symmetrically disposed with respect to the imaginary line Cen in plan view.

As illustrated in FIG. 19, interconnections 251, 252, and 253 and the data lines 14 are provided by patterning the third interconnection layer 250.

The interconnection 251 is disposed to extend in the Y direction including the imaginary line Cen, and is coupled to the interconnection 241 via a large number of contact holes Ct21 as described later.

The data line 14 is disposed to extend in the Y direction and is coupled to the interconnection 243 via a contact hole. Therefore, the source node of the transistor 122 and the drain node of the transistor 123 are coupled to the data line 14 via the interconnections 234 and 243 in order.

The interconnection 252 is disposed along the Y direction so as to sandwich the data line 14 together with the interconnection 251 in the left-right direction in plan view. The interconnection 252 is coupled to the interconnection 241 via a large number of contact holes Ct22 as described later.

The interconnection 253 is a relay interconnection disposed along the Y direction and for guiding the drain node of the transistor 124 to the pixel electrode 131. Therefore, the interconnection 253 is coupled to the interconnection 244 via a contact hole.

As illustrated in FIG. 19, the interconnections 251, 252 and the data line 14 in two pixel circuits which are the same in color, are adjacent along the X direction to each other, and exclude the display elements are symmetrically disposed with respect to the imaginary line Cen in plan view.

As shown in FIG. 20, the interconnections 261 and 263 are provided by patterning the fourth interconnection layer 260.

The interconnection 263 is a relay interconnection for guiding the drain node of the transistor 124 to the pixel electrode 131. Therefore, the interconnection 263 is coupled to the interconnection 252 via a contact hole.

The interconnection 261 is an interconnection extending over the display region 100, but opens in openings Ap in order to avoid the interconnections 263 in the same layer. In other words, the interconnections 263 are disposed in the openings Ap of the interconnection 261. As described later, the interconnection 261 is coupled to the interconnections 251 via a large number of contact holes Ct31, and is also coupled to the interconnections 252 via a large number of contact holes Ct32.

In the drawing, the interconnection 261 is hatched for the sake of convenience.

As illustrated in FIG. 21, the pixel electrode 131 is provided by patterning the pixel electrode layer. The pixel electrode 131 is coupled to the interconnection 263 via a contact hole. Therefore, the drain node of the transistor 124 is coupled to the pixel electrode 131 via the interconnections 236, 244, 253, and 263 in this order.

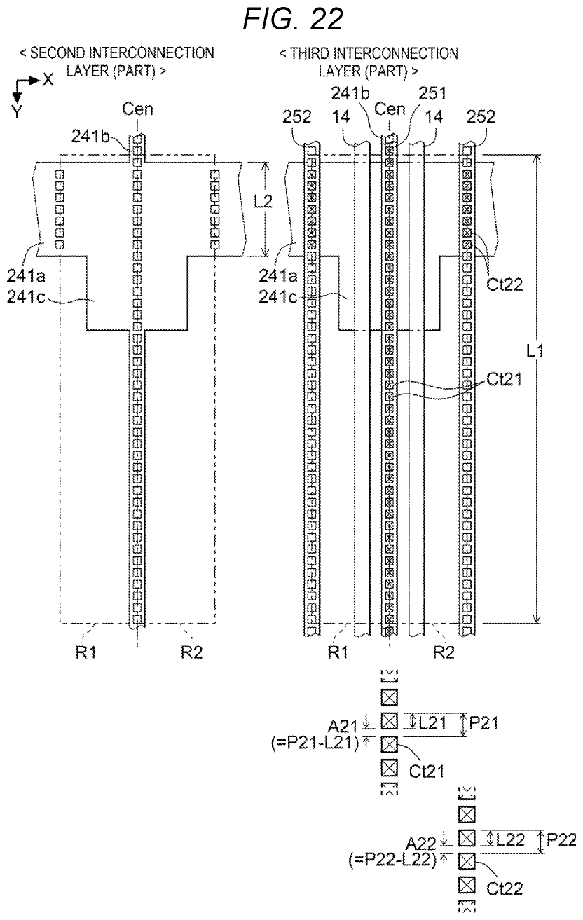

FIG. 22 is a plan view illustrating a contact hole paying attention to the contact hole that couples the interconnection 241 in the second interconnection layer 240 and the interconnection 251 or the interconnection 252 in the third interconnection layer 250 to each other. Specifically, the drawing is a plan view illustrating the contact hole Ct21 for coupling the interconnection 251 and the extending portion 241b of the interconnection 241 to each other and the contact hole Ct22 for coupling the interconnection 252 and the extending portion 241a of the interconnection 241 to each other.

For the sake of convenience, the length in the Y direction of the pixel circuit 110 excluding the display element is denoted by L1.

In the display region 100, the extending portion 241b extends along the Y direction, and the interconnection 251 also extends along the Y direction. The extending portion 241b and the interconnection 251 overlap each other in substantially the entire area of the display region 100 along the Y direction. The contact holes Ct21 are arranged at intervals P21 along the Y direction in which the extending portion 241b and the interconnection 251 overlap each other.

In the present embodiment, the shape of the contact hole Ct21 is a square in plan view, and the square is L21 on a side.

When the length of the gap between the contact holes Ct21 adjacent in the Y direction to each other is A21, the length A21 is a value obtained by subtracting the length L21 from the interval P21. In the present embodiment, the lengths L21 and A21 have the following relationship.

L21>A21

When the region where the extending portion 241b and the interconnection 251 overlap in plan view is sectioned by the length L1 of the pixel circuit 110, the total length (coupling length) in the Y direction coupled by the plurality of contact holes Ct21 is longer than the total length (non-coupling length) not coupled by the contact holes Ct21.

In the display region 100, the extending portion 241a extending in the X direction out of the interconnection 241 overlaps the interconnection 252 extending in the Y direction with a width (length) L2. The contact holes Ct22 are arranged at intervals P22 along the Y direction in the extending portion 241a and the interconnection 252.

In the present embodiment, the shape of the contact hole Ct22 is a square in plan view, and the square is L22 on a side.

When the length of the gap between the contact holes Ct21 adjacent in the Y direction to each other is A22, the length A22 is a value obtained by subtracting the length L22 from the interval P22. In the present embodiment, the lengths L22 and A22 have the following relationship.

L22>A22

When the region where the extending portion 241a and the interconnection 252 overlap in plan view is sectioned by the length L2 along the Y direction, the total length (coupling length) in the Y direction coupled by the plurality of contact holes Ct22 is longer than the total length (non-coupling length) not coupled by the contact holes Ct22.

Since the contact holes Ct21, Ct22 penetrate the fourth interlayer insulating film 284 located between the second interconnection layer 240 and the third interconnection layer 250, to be exact, the lengths L21, L22 are lengths of penetrated portions along the Y direction in the uppermost surface of the fourth interlayer insulating film 284.

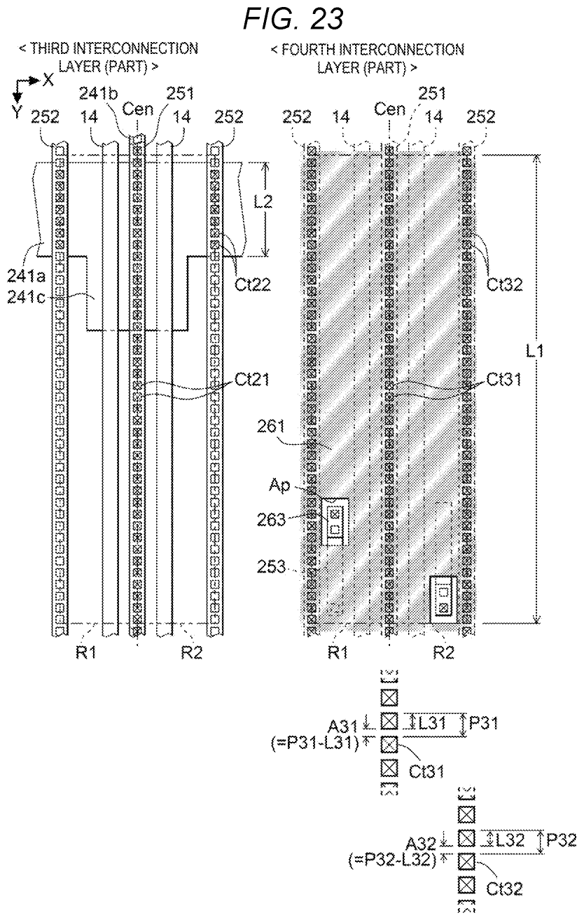

FIG. 23 is a plan view illustrating the contact holes Ct31 for coupling the interconnections 251 of the third interconnection layer 250 and the interconnection 261 of the fourth interconnection layer 260, and the contact holes Ct32 for coupling the interconnections 252 and the interconnection 261.

In the display region 100, the interconnection 251 extends along the Y direction, and the interconnection 261 spreads substantially all around except the openings Ap. Therefore, the interconnection 261 overlaps the interconnections 251 in substantially the entire area of the display region 100 in plan view. The contact holes Ct31 are arranged at intervals P31 along the Y direction in which the interconnection 251 and the interconnection 261 overlap each other.

In the present embodiment, the shape of the contact hole Ct31 is a square in plan view, and the square is L31 on a side.

When the length of the gap between the contact holes Ct31 adjacent in the Y direction to each other is A31, the length A31 is a value obtained by subtracting the length L31 from the interval P31. In the present embodiment, the lengths L31 and A31 have the following relationship.

L31>A31

When the region where the interconnections 251 and 261 overlap in plan view is sectioned by the length L1 of the pixel circuit 110, the total length (coupling length) in the Y direction coupled by the plurality of contact holes Ct31 is longer than the total length (non-coupling length) not coupled by the contact holes Ct31.

In the display region 100, the interconnection 252 extends along the Y direction. Therefore, the interconnection 261 overlaps the interconnections 252 in substantially the entire area of the display region 100 in plan view. The contact holes Ct32 are arranged at intervals P32 along the Y direction in which the interconnection 252 and the interconnection 261 overlap each other.

In the present embodiment, the shape of the contact hole Ct32 is a square in plan view, and the square is L32 on a side.

When the length of the gap between the contact holes Ct32 adjacent in the Y direction to each other is A32, the length A32 is a value obtained by subtracting the length L32 from the interval P32. In the present embodiment, the lengths L32 and A32 have the following relationship.

L32>A32

When the region where the interconnections 252 and 261 overlap in plan view is sectioned by the length L1 of the pixel circuit 110, the total length (coupling length) in the Y direction coupled by the plurality of contact holes Ct32 is longer than the total length (non-coupling length) not coupled by the contact holes Ct32.

The superiority of the electro-optical device 10 according to the present embodiment will be described with reference to FIG. 14 once again.

In the present embodiment, the data line 14 provided by patterning the third interconnection layer 250 is laterally adjacent to the interconnections 251 and 252 also provided by patterning the third interconnection layer 250. Specifically, in the drawing, the interconnection 251 is located at the right side of the data line 14 corresponding to the pixel circuit 110R1, and the interconnection 252 is located at the left side thereof. In the drawing, the interconnection 252 is located at the right side of the data line 14 corresponding to the pixel circuit 110R2, and the interconnection 251 is located at the left side thereof.

In addition, the interconnection 241 is provided by patterning the second interconnection layer 240 in the lower layer of the data line 14, and the interconnection 261 is provided by patterning the fourth interconnection layer 260 in the upper layer of the data line 14.

The interconnection 241 (the extending portion 241a) and the interconnection 251 are coupled via the contact holes Ct21 arranged at the intervals P21, and the interconnection 241 (the extending portion 241a) and the interconnection 252 are coupled via the contact holes Ct22.

The interconnection 261 and the interconnection 251 are coupled via the contact holes Ct31 arranged at the intervals P31, and the interconnection 261 and the interconnection 252 are coupled via the contact holes Ct32 arranged at the intervals P32.

Since the interconnection 241 is coupled to the interconnection 231 at the voltage Vel via the contact holes Ct11 (see FIGS. 16, 17, and 18), the voltage Vel is also applied to the interconnections 241, 251, 252, and 261. Therefore, in FIG. 14, the data line 14 is surrounded by the interconnections 241, 251, 252, and 261 to which the voltage Vel is applied at the opposite side in the Z direction, the side in the X direction, the opposite side in the X direction, and the side in the Z direction.

Further, the contact holes Ct21 partition the fourth interlayer insulating film 284 in a wall shape with a dense arrangement along the Y direction from the interconnection 251 to the extending portion 241b. Similarly, the contact holes Ct22 partition the fourth interlayer insulating film 284 in a wall shape with a dense arrangement along the Y direction from the interconnection 252 to the extending portion 241a. Further, the contact holes Ct31 partition the fifth interlayer insulating film 285 in a wall shape with a dense arrangement along the Y direction from the interconnection 261 to the interconnection 251. Similarly, the contact holes Ct32 partition the fifth interlayer insulating film 285 in a wall shape with a dense arrangement along the Y direction from the interconnection 261 to the interconnection 252.

For this reason, since the data line 14 is shielded by the interconnection and the contact holes at the voltage Vel over substantially all directions in a cross-sectional view, the voltage fluctuation in the data line 14 is suppressed from propagating to other interconnections or electrodes via the parasitic capacitance. Therefore, in the present embodiment, it is possible to prevent the deterioration of the display quality caused by the voltage fluctuation in the data line 14.

In the embodiment, for example, since the same one interconnection 251 is shared between the pixel circuit 110R1 and the pixel circuit 110R2, the number of interconnections is reduced by one compared to a configuration in which two interconnections 251 are prepared so as to correspond one-to-one to the pixel circuit 110R1 and the pixel circuit 110R2. Therefore, in the embodiment, it is easy to narrow the interval between the pixel circuits 110 along the X direction, and it is easy to achieve the high resolution and high definition.

In the embodiment, the shapes of the contact holes Ct21, Ct22, Ct31, and Ct32 are each a square in plan view, but this is not a limitation.

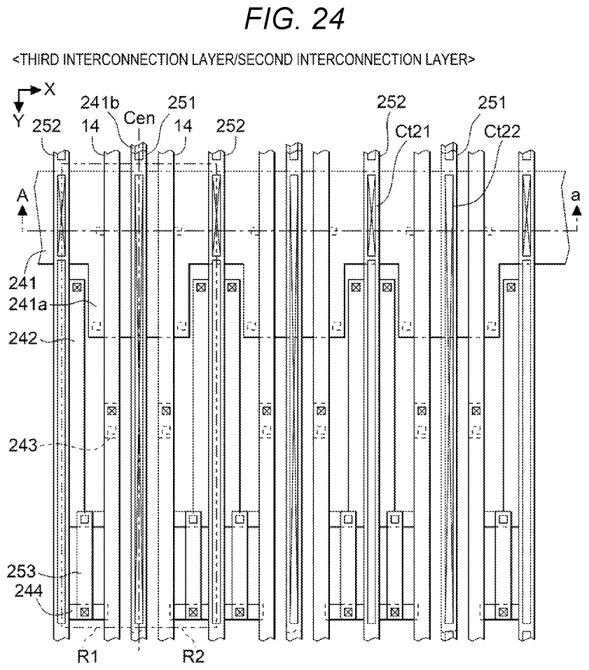

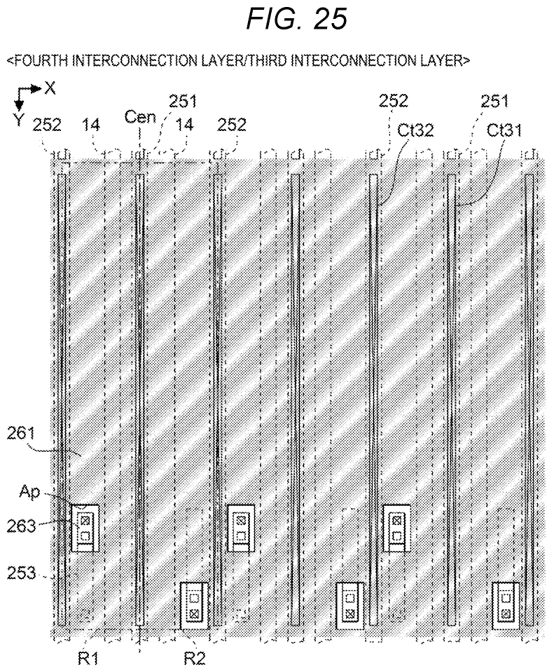

FIGS. 24 and 25 are each a plan view showing a shape of a contact hole according to a modified example. As illustrated in FIG. 24 regarding the contact holes Ct21, Ct22 and as illustrated in FIG. 25 regarding the contact holes Ct31 and Ct32, rectangular shapes elongated in the Y direction may be adopted.

The shape of the contact holes Ct21, Ct22, Ct31, and Ct32 is not limited to a quadrangle such as a square or a rectangle, and may be a circle to achieve a dense arrangement, or may be an elliptic circle elongated in the Y direction. In any shapes, it is sufficient that the coupling length by the contact holes in plan view is longer than the non-coupling length when sectioning the region by the length L1 or L2.

In the embodiment, the OLED 130 has been described as an example of the display element, but other display elements may be used. For example, an LED, a mini LED, a micro LED, or the like may be used as the display element.

Channel types of the transistors 121, 122, 123, and 124 are not limited to the embodiment and the like. These transistors may be appropriately replaced with a transmission gate except for the transistor 121.

The transmission gates 45, 72, and 73 may be replaced with a single-channel transistor.

Next, an electronic instrument to which the electro-optical device 10 according to the embodiment and the like is applied will be described. The electro-optical device 10 is suitable for applications in which pixels are small and high-definition display is performed. Therefore, a head-mounted display will be described as an example of the electronic apparatus.

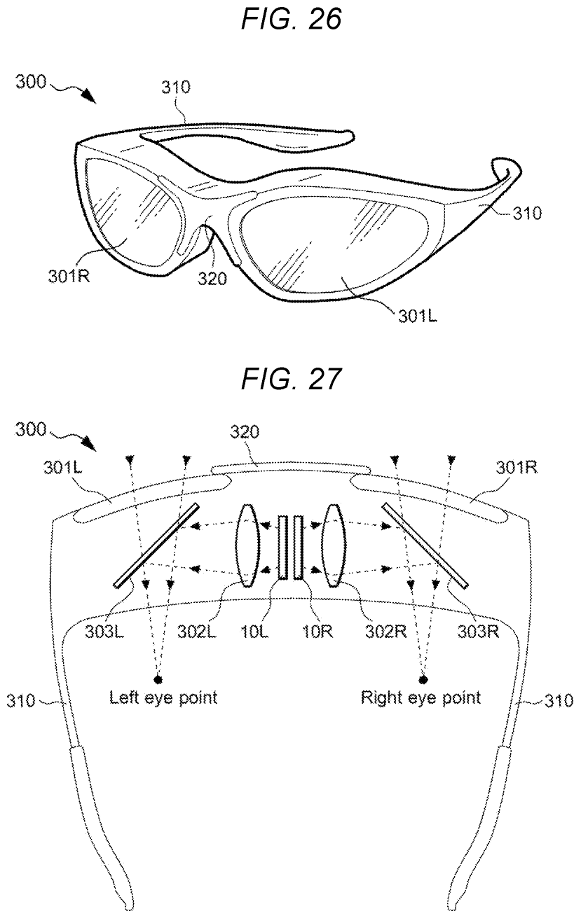

FIG. 26 is a diagram illustrating an appearance of the head-mounted display, and FIG. 27 is a diagram illustrating an optical configuration of the head-mounted display.

First, as illustrated in FIG. 26, a head-mounted display 300 includes temples 310, a bridge 320, and lenses 301L, 301R similarly in appearance to general glasses. Further, as illustrated in FIG. 27, the head-mounted display 300 includes an electro-optical device 10L for a left eye and an electro-optical device 10R for a right eye that are disposed near the bridge 320 and at a back side of the lenses 301L, 301R (lower side in the drawing).

An image display surface of the electro-optical device 10L is disposed on the left in FIG. 27. Accordingly, a display image by the electro-optical device 10L is emitted in a direction of 9 o'clock in the drawing via an optical lens 302L. A half mirror 303L reflects a display image by the electro-optical device 10L in a direction of 6 o'clock, while transmitting light entering from a direction of 12 o'clock. An image display surface of the electro-optical device 10R is disposed on the right opposite to the electro-optical device 10L. Accordingly, a display image by the electro-optical device 10R is emitted in a direction of 3 o'clock in the drawing via an optical lens 302R. A half mirror 303R reflects a display image by the electro-optical device 10R in a direction of 6 o'clock, while transmitting light entering from a direction of 12 o'clock.

In this configuration, a wearer of the head-mounted display 300 can observe display images by the electro-optical devices 10L and 10R in a see-through state superimposed over the external scenery.

Further, in the head-mounted display 300, when the electro-optical device 10L displays an image for the left eye and the electro-optical device 10R displays an image for the right eye out of binocular images with parallax, the wearer can perceive the displayed image as if the displayed image had a depth or a stereoscopic effect.

The electronic instrument including the electro-optical device 10 can be used not only as the head-mounted display 300, but also as an electronic viewfinder in a video camera and an interchangeable-lens digital camera, a portable information terminal, a display unit in wristwatches, and a light valve in a projection projector.

From the above description, for example, preferred aspects of the present disclosure are understood as follows.

An electro-optical device according to Aspect 1 of the present disclosure includes: a first interconnection, a first data line, and a second interconnection which are formed of a first interconnection layer; a first pixel circuit configured to take an optical state according to a data signal supplied to the first data line; a lower layer interconnection formed of an interconnection layer as a lower layer of the first interconnection layer; and an upper layer interconnection formed of an interconnection layer as an upper layer of the first interconnection layer, wherein the first interconnection, the first data line, and the second interconnection extend along a first direction and are arranged in order in a second direction, the lower layer interconnection overlaps the first interconnection and the second interconnection in plan view, the upper layer interconnection overlaps the first interconnection and the second interconnection in plan view, the first interconnection and the lower layer interconnection are coupled via a first contact hole configured to penetrate a first insulating layer, a coupling length by the first contact hole is longer than a non-coupling length per first unit length along the first direction, the second interconnection and the lower layer interconnection are coupled via a second contact hole configured to penetrate the first insulating layer, a coupling length by the second contact hole per second unit length along the first direction is longer than a non-coupling length per second unit length along the first direction, the first interconnection and the upper layer interconnection are coupled via a third contact hole configured to penetrate a second insulating layer, a coupling length by the third contact hole is longer than a non-coupling length per the first unit length, the second interconnection and the upper layer interconnection are coupled via a fourth contact hole configured to penetrate the second insulating layer, and a coupling length by the fourth contact hole is longer than a non-coupling length per the first unit length.

In the electro-optical device according to Aspect 1, the first data line is interposed between the first interconnection and the second interconnection in plan view. The first interconnection is coupled to the lower layer interconnection via the first contact hole densely arranged, and is coupled to the upper layer interconnection via the third contact hole densely arranged. Similarly, the second interconnection is coupled to the lower layer interconnection via the second contact hole densely arranged, and is coupled to the upper layer interconnection via a fourth contact hole densely arranged. Therefore, in the electro-optical device according to Aspect 1, since the first data line is not only planarly shielded by the first interconnection and the second interconnection but also shielded by the first contact hole and the second contact hole having a wall shape in an oblique direction in a cross-sectional view, it is possible to suppress the voltage variation of the first data line from propagating through the parasitic capacitance generated in the insulating layer.

The third interconnection layer 250 is an example of the “first interconnection layer”, the interconnection 251 is an example of the “first interconnection”, and the interconnection 252 is an example of the “second interconnection”. The pixel circuit 110R1 is an example of the “first pixel circuit”, the interconnection 241 is an example of the “lower layer interconnection”, and the interconnection 261 is an example of the “upper layer interconnection”.

The Y direction is an example of the “first direction”, and the X direction is an example of the “second direction”. The fourth interlayer insulating film 284 is an example of the “first insulating layer”, and the fifth interlayer insulating film 285 is an example of the “second insulating layer”.

The contact hole Ct21 is an example of the “first contact hole”, the contact hole Ct22 is an example of the “second contact hole”, the contact hole Ct31 is an example of the “third contact hole”, and the contact hole Ct32 is an example of the “fourth contact hole”. The length L1 is an example of the “first unit length”, and the length L2 is an example of the “second unit length”.

In the electro-optical device according to Aspect 2 as a specific aspect of Aspect 1, the lower layer interconnection overlaps the first data line and is continuous along the second direction in plan view, and the upper layer interconnection overlaps the first data line and is continuous along the second direction in plan view.

According to the electro-optical device related to Aspect 2, since the lower layer interconnection is located below the first data line and the upper layer interconnection is located above the first data line in a cross-sectional view, it is possible to suppress the voltage variation of the first data line from propagating in the vertical direction via the parasitic capacitance.

In the electro-optical device according to Aspect 3 as another specific aspect of Aspect 1, the first pixel circuit includes a display element, and a first transistor configured to control a current flowing through the display element, and a channel region of the first transistor is disposed between the first interconnection and the second interconnection in plan view.

According to the electro-optical device related to Aspect 3, since the first transistor is interposed between the first interconnection and the second interconnection in plan view, it is possible to make it difficult to be affected by noise. The first transistor may be covered with a lower layer interconnection. In addition, the OLED 130 is an example of the “display element”, and the transistor 121 is an example of the “first transistor”.

In the electro-optical device according to Aspect 4 as a specific aspect of Aspect 3, a power supply voltage is applied to the lower layer interconnection, and the first transistor includes a gate electrode and controls the current flowing through the display element from the lower layer interconnection in accordance with a voltage of the gate electrode.

According to the electro-optical device related to Aspect 4, since the power supply voltage is applied to the interconnections 241, 251, 252, and 261 that function as shield interconnections, it is possible to simplify the power supply circuit compared to a configuration in which another voltage is applied. The voltage Vel is an example of the “power supply voltage”.

The electro-optical device according to Aspect 5 as a specific aspect of Aspect 4, further includes a scanning line along the second direction, wherein the first pixel circuit includes, between the first data line and the gate electrode, a second transistor configured to take an on state or an off state in accordance with a voltage of the scanning line.

According to the electro-optical device related to Aspect 5, the on state and the off state between the first data line and the gate electrode of the first transistor are switched in accordance with the voltage of the scanning line. The transistor 122 is an example of the “second transistor”.

The electro-optical device according to Aspect 6 as another specific aspect of Aspect 1 further includes a second data line that is formed of the first interconnection layer and is disposed along the first direction; and a second pixel circuit configured to take an optical state according to a data signal supplied to the second data line, wherein the second data line is located at a position symmetrical to the first data line in plan view with respect to the first interconnection, and the second pixel circuit is located at a position symmetrical to the first pixel circuit in plan view with respect to the first interconnection.

According to the electro-optical device related to Aspect 6, since one first interconnection is shared between the first pixel circuit and the second pixel circuit, it is easy to narrow the interval between the pixel circuits along the second direction compared to a configuration in which separate first interconnections are provided respectively to the first pixel circuit and the second pixel circuit. The pixel circuit 110R2 is an example of the “second pixel circuit”.

An electronic apparatus according to Aspect 7 includes the electro-optical device according to any one of Aspects 1 to 6.

What is claimed is:

1. An electro-optical device comprising:
a first interconnection, a first data line, and a second interconnection which are formed of a first interconnection layer;
a first pixel circuit configured to take an optical state according to a data signal supplied to the first data line;
a lower layer interconnection formed of an interconnection layer as a lower layer of the first interconnection layer; and
an upper layer interconnection formed of an interconnection layer as an upper layer of the first interconnection layer, wherein
the first interconnection, the first data line, and the second interconnection extend along a first direction and are arranged in order in a second direction,
the lower layer interconnection overlaps the first interconnection and the second interconnection in plan view,
the upper layer interconnection overlaps the first interconnection and the second interconnection in plan view,
the first interconnection and the lower layer interconnection are coupled via a first contact hole configured to penetrate a first insulating layer,
a coupling length by the first contact hole is longer than a non-coupling length per first unit length along the first direction,
the second interconnection and the lower layer interconnection are coupled via a second contact hole configured to penetrate the first insulating layer,
a coupling length by the second contact hole is longer than a non-coupling length per second unit length along the first direction,
the first interconnection and the upper layer interconnection are coupled via a third contact hole configured to penetrate a second insulating layer,
a coupling length by the third contact hole is longer than a non-coupling length per the first unit length,
the second interconnection and the upper layer interconnection are coupled via a fourth contact hole configured to penetrate the second insulating layer, and
a coupling length by the fourth contact hole is longer than a non-coupling length per the first unit length.

2. The electro-optical device according to claim 1, wherein
the lower layer interconnection overlaps the first data line and is continuous along the second direction in plan view, and
the upper layer interconnection overlaps the first data line and is continuous along the second direction in plan view.

3. The electro-optical device according to claim 1, wherein
the first pixel circuit includes
a display element, and
a first transistor configured to control a current flowing through the display element, and
a channel region of the first transistor is disposed between the first interconnection and the second interconnection in plan view.

4. The electro-optical device according to claim 3, wherein
a power supply voltage is applied to the lower layer interconnection, and
the first transistor includes a gate electrode and controls the current flowing through the display element from the lower layer interconnection in accordance with a voltage of the gate electrode.

5. The electro-optical device according to claim 4, further comprising
a scanning line along the second direction, wherein
the first pixel circuit includes, between the first data line and the gate electrode, a second transistor configured to take an on state or an off state in accordance with a voltage of the scanning line.

6. The electro-optical device according to claim 1, comprising:
a second data line that is formed of the first interconnection layer and is disposed along the first direction; and
a second pixel circuit configured to take an optical state according to a data signal supplied to the second data line, wherein
the second data line is located at a position symmetrical to the first data line in plan view with respect to the first interconnection, and
the second pixel circuit is located at a position symmetrical to the first pixel circuit in plan view with respect to the first interconnection.

7. An electronic apparatus comprising
the electro-optical device according to claim 1.
